(19) United States
(12) Patent Application Publication
(10) Pub. No.: US 2025/0081445 A1
(43) Pub. Date: Mar. 6, 2025

(54) SEMICONDUCTOR MEMORY DEVICE

(71) Applicant: Samsung Electronics Co., Ltd., Suwon-si (KR)

(72) Inventors: Bo Won Yoo, Suwon-si (KR); Seok Han Park, Suwon-si (KR); Keun Ui Kim, Suwon-si (KR); Yu Jin Kim, Suwon-si (KR); Joong Chan Shin, Suwon-si (KR); Gyu Hwan Oh, Suwon-si (KR); Eun Suk Jang, Suwon-si (KR); Jin Woo Han, Suwon-si (KR)

(21) Appl. No.: 18/660,803

(22) Filed: May 10, 2024

(30) Foreign Application Priority Data
Sep. 4, 2023 (KR) 10-2023-0117110

(51) Int. Cl. H10B 12/00

(52) U.S. Cl. CPC H10B 12/482; H10B 12/315; H10B 12/485; H10B 12/488

(57) ABSTRACT

A semiconductor memory device includes a bit line extending in a first direction on a substrate, an active pattern on the bit line, a word line on a first sidewall of the active pattern and extending in a second direction, a back gate electrode on a second sidewall of the active pattern and extending in the second direction, a gate isolation pattern on the first sidewall of the active pattern and including a low-k pattern extending in the second direction, and a data storage pattern connected to the second surface of the active pattern. The word line is between the active pattern and the gate isolation pattern, and a vertical distance between the bit line and the word line is greater than a vertical distance between the bit line and the low-k pattern.

### CROSS-REFERENCE TO RELATED APPLICATION(S)

This application claims priority from Korean Patent Application No. 10-2023-0117110 filed on Sep. 4, 2023 in the Korean Intellectual Property Office, and all the benefits accruing therefrom under 35 U.S.C. § 119, the contents of which in its entirety are herein incorporated by reference.

### BACKGROUND

The present disclosure relates generally to a semiconductor memory device, and more particularly, to a semiconductor memory device including a vertical channel transistor (VCT).

In order to satisfy consumer demands for superior performance and inexpensive prices, it is desired to increase the integration density of semiconductor memory devices. In a semiconductor memory device, since the integration density of the semiconductor memory device is an important factor in determining the price of a product, an increased integration density, which generally leads to reduced cost, is particularly required.

In the case of a two-dimensional or planar semiconductor memory device, the integration density is mainly determined by the area occupied by a unit memory cell, and thus the integration density is greatly influenced by the level of fine pattern formation technology. However, since extremely high-priced equipment is required for the miniaturization of patterns, the integration density of the two-dimensional semiconductor memory device, although it has been increased, practical limitations remain. Accordingly, semiconductor memory devices including vertical channel transistors in which a channel extends in a vertical direction have been proposed.

### SUMMARY

Aspects of the present disclosure provide a semiconductor memory device with an improved integration density and electrical characteristics.

However, aspects of the present disclosure are not restricted to the advantages set forth herein. The above and other aspects of the present disclosure will become more apparent to one of ordinary skill in the art to which the present disclosure pertains by referencing the detailed description of the present disclosure given below in conjunction with the accompanying drawings.

According to an aspect of the present disclosure, there is provided a semiconductor memory device comprising a bit line extending in a first direction on a substrate, an active pattern on the bit line, and comprising a first sidewall and a second sidewall opposite to each other in the first direction, and a first surface and a second surface opposite to each other in a vertical direction, the first surface of the active pattern being connected to an active pattern connected to the bit line, a word line on a first sidewall of the active pattern, and extending in a second direction, a back gate electrode on a second sidewall of the active pattern, and extending in the second direction, a gate isolation pattern on a first sidewall of the active pattern, and comprising a low-k pattern extending in the second direction and a data storage pattern connected to the second surface of the active pattern, wherein the word line is between the active pattern and the gate isolation pattern, and a distance between the bit line and the word line in the vertical direction is greater than a distance between the bit line and the low-k pattern in the vertical direction.

According to an aspect of the present disclosure, there is provided a semiconductor memory device comprising a bit line extending in a first direction on a substrate, a first active pattern on the bit line, a second active pattern on the bit line, and spaced apart from the first active pattern in the first direction, a first word line between the first active pattern and the second active pattern, and extending in a second direction, a second word line between the first active pattern and the second active pattern, extending in the second direction, and spaced apart from the first word line in the first direction, a gate isolation pattern between the first word line and the second word line on the bit line, and comprising a low-k pattern extending in the second direction, a back gate electrode on the bit line, spaced apart from the first word line and the second word line in the first direction, and extending in the second direction and data storage patterns connected to the first active pattern and the second active pattern, wherein a height of the low-k pattern in the vertical direction is greater than a height of the first word line in the vertical direction.

According to an aspect of the present disclosure, there is provided a semiconductor memory device comprising a peri-gate structure on a substrate, a shielding conductive pattern on the peri-gate structure, and comprising a shielding conductive plate and a plurality of shielding conductive protrusion patterns protruding (i.e., extending) from the shielding conductive plate, each shielding conductive protrusion pattern extending in a first direction, bit lines between the shielding conductive protrusion patterns adjacent to each other in a second direction, on the shielding conductive plate, back gate electrodes on the bit line, and extending in the second direction, a first word line and a second word line between the back gate electrodes adjacent in the first direction on the bit line, and extending in the second direction, first active patterns between the back gate electrode and the first word line, connected to the bit line, and arranged in the second direction, second active patterns between the back gate electrode and the second word line, connected to the bit line, and arranged in the second direction, a gate isolation pattern between the first word line and the second word line on the bit line, and comprising at least one low-k pattern extending in the second direction and data storage patterns connected to the first active patterns and the second active patterns, wherein a height of the low-k pattern in the vertical direction is greater than a height of the first word line in the vertical direction, the low-k pattern comprises one of an air gap and a low-k material, and a dielectric constant of the low-k material is smaller than that of silicon oxide.

### BRIEF DESCRIPTION OF THE DRAWINGS

The above and other aspects and features of the present disclosure will become more apparent by describing in detail example embodiments thereof with reference to the attached drawings, wherein like reference numerals (when used) indicate corresponding elements throughout the several views, and in which:

FIG. 1 is a layout diagram illustrating an example semiconductor memory device according to some embodiments;

FIG. 2 is a layout diagram (plan view) of a boundary portion between a cell array region and a peripheral circuit region of the semiconductor memory device shown in FIG. 1;

FIG. 3 is a cross-sectional view of the semiconductor memory device shown in FIG. 2 taken along lines A-A and B-B;

FIG. 4 is a cross-sectional view of the semiconductor memory device shown in FIG. 2 taken along lines C-C and D-D;

FIG. 5 is an enlarged view of a region P of the semiconductor memory device shown in FIG. 4;

FIG. 6 is an enlarged view of a region Q of the semiconductor memory device shown in FIG. 4;

FIGS. 7 to 16 are cross-sectional views each illustrating an example semiconductor memory device, according to one or more embodiments;

FIGS. 17 and 18 are cross-sectional views each illustrating portions of an example semiconductor memory device according to some embodiments;

FIGS. 19 and 20 are plan and cross-sectional views, respectively, illustrating an example semiconductor memory device according to some embodiments;

FIGS. 21 and 22 are plan and cross-sectional views, respectively, illustrating an example semiconductor memory device according to some embodiments;

FIGS. 23 to 26 are plan views each illustrating a semiconductor memory device according to some embodiments; and

FIGS. 27 to 52 are views illustrating intermediate processes in an example method for fabricating a semiconductor memory device, according to one or more embodiments.

### DETAILED DESCRIPTION

Although ordinal terms such as first, second, etc., may be used herein to describe various elements or components, these elements or components should not be limited by these terms. These terms are used to distinguish one element or component from another element or component. Thus, a first element or component discussed below could be termed a second element or component without departing from the teachings of the present disclosure.

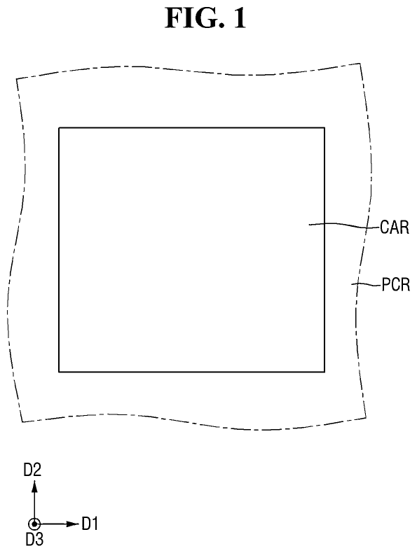

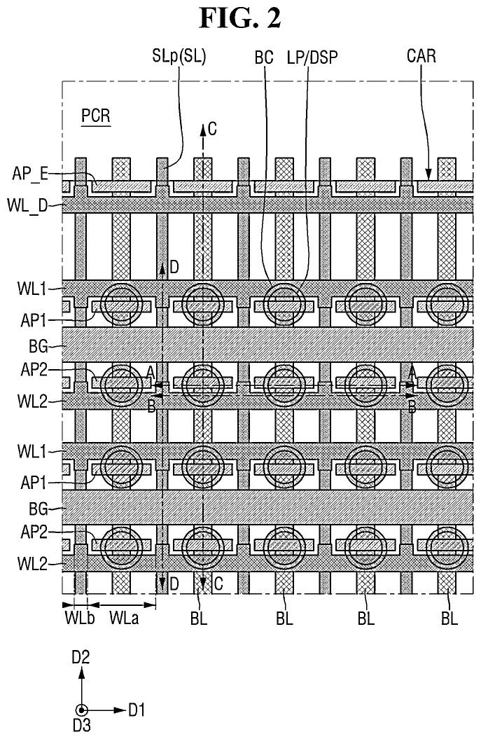

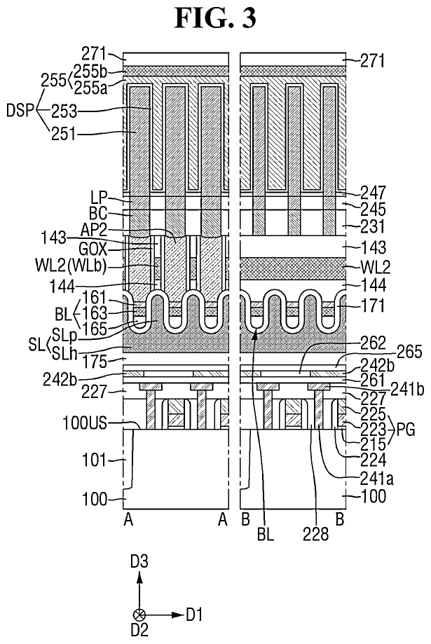

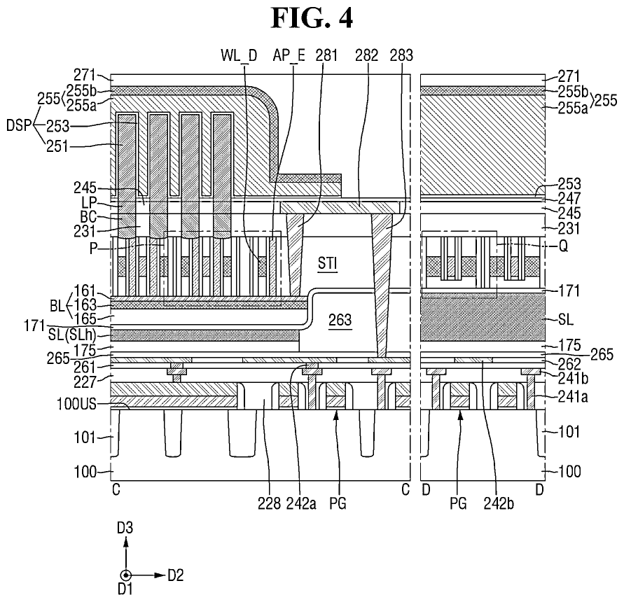

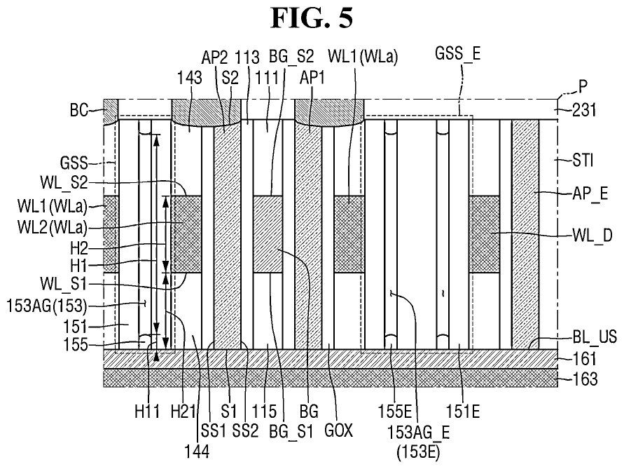

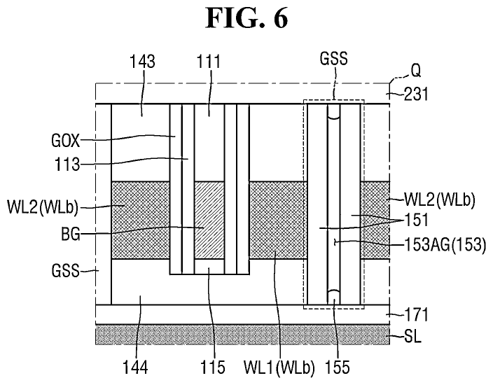

FIG. 1 is a layout diagram illustrating a semiconductor memory device according to some embodiments. FIG. 2 is a layout diagram (in plan view) of a boundary portion between a cell array region and a peripheral circuit region of the semiconductor memory device shown in FIG. 1. FIG. 3 is a cross-sectional view of the semiconductor memory device shown in FIG. 2, taken along lines A-A and B-B. FIG. 4 is a cross-sectional view of the semiconductor memory device shown in FIG. 2, taken along lines C-C and D-D. FIG. 5 is an enlarged view of a region P of the semiconductor memory device shown in FIG. 4. FIG. 6 is an enlarged view of a region Q of the semiconductor memory device shown in FIG. 4.

The semiconductor memory device according to embodiments of the present disclosure may include memory cells including a vertical channel transistor (VCT).

Referring to FIGS. 1 to 6, the semiconductor memory device according to some embodiments may include bit lines BL, word lines WL1 and WL2, back gate electrodes BG, a shielding conductive pattern SL, active patterns AP1 and AP2, gate isolation patterns GSS, an outermost gate isolation pattern GSS_E, and data storage patterns DSP.

The semiconductor memory device includes a substrate 100, which may be a silicon substrate, or may include other materials such as silicon germanium, indium antimonide, lead tellurium compound, indium arsenide, indium phosphide, gallium arsenide, or gallium antimonide, but is not limited thereto.

The substrate 100 may include a top surface 100US. An element isolation layer 101 (e.g., shallow trench isolation (STI)) may be disposed (i.e., provided) in the substrate 100. The element isolation layer 101 may define an active area in the substrate 100. The element isolation layer 101 includes an insulating material.

The substrate 100 may include a cell array region CAR where the data storage pattern DSP is disposed, and a peripheral circuit region PCR defined around the cell array region CAR. A cell region element isolation layer STI may be disposed on the peripheral circuit region PCR of the substrate 100. In plan view, the cell region element isolation layer STI may define the cell array region CAR of the substrate 100.

A peri-gate structure PG may be disposed on the substrate 100. For example, the peri-gate structure PG may be disposed on the top surface 100US of the substrate. The peri-gate structure PG may be disposed across the cell array region CAR and the peripheral circuit region PCR. In other words, a part of the peri-gate structure PG may be disposed in the cell array region CAR of the substrate 100, and the remaining part of the peri-gate structure PG may be disposed in the peripheral circuit region PCR of the substrate 100.

The peri-gate structure PG may be included, for example, in a sensing transistor, a transmission transistor, a driving transistor, and the like. For example, the peri-gate structure PG included in the sensing transistor may be disposed on the substrate 100 in the cell array region CAR, but is not limited thereto. The type of a transistor of a peripheral circuit disposed on the substrate 100 in the cell array region CAR may vary depending on the design layout of the semiconductor memory device.

The peri-gate structure PG may include a peri-gate insulating layer 215, a peri-lower conductive pattern 223, and a peri-upper conductive pattern 225. The peri-gate insulating layer 215 may include, for example, a silicon oxide layer, a silicon oxynitride layer, a high dielectric constant (high-k) insulating layer having a dielectric constant higher than that of the silicon oxide layer, or a combination thereof, although embodiments are not limited thereto. The high-k insulating layer may include, for example, at least one of metal oxide, metal oxynitride, metal silicon oxide, or metal silicon oxynitride, but is not limited thereto.

Each of the peri-lower conductive pattern 223 and the peri-upper conductive pattern 225 includes a conductive material. For example, the peri-lower conductive pattern 223 and the peri-upper conductive pattern 225 may each include at least one of a doped semiconductor material, conductive metal nitride, conductive metal silicon nitride, metal carbonitride, conductive metal silicide, conductive metal oxide, a 2D material, or metal, although embodiments are not limited thereto. In the semiconductor memory device according to some embodiments, the 2D material may be a metallic material and/or a semiconductor material. The 2D material may include a 2D allotrope or a 2D compound. For example, it may include at least one of graphene, molybdenum disulfide (MoS₂), molybdenum diselenide (MoSe₂), tungsten diselenide (WSe₂), or tungsten disulfide (WS₂), but is not limited thereto. That is, since the above-mentioned 2D materials are merely examples, the 2D materials that may be included in the semiconductor memory device of the present disclosure are not limited thereto. Although the peri-gate structure PG is illustrated as including a plurality of conductive patterns, it is not limited thereto.

A peri-gate spacer 224 may be disposed on the sidewall of the peri-gate structure PG. The peri-gate spacer 224 includes an insulating material.

Although not shown in the drawings, the peri-gate structure PG may further include a peri-gate mask pattern disposed on the peri-upper conductive pattern 225. The peri-gate mask pattern is made of an insulating material.

A first peri-lower insulating layer 227 and a second peri-lower insulating layer 228 are disposed on the top surface 100US of the substrate. The first peri-lower insulating layer 227 and the second peri-lower insulating layer 228 each include an insulating material.

A peri-contact plug 241a and a peri-wiring line 241b may be disposed in the first peri-lower insulating layer 227 and the second peri-lower insulating layer 228; the peri-contact plug 241a may extend vertically (in a direction D3) into the first peri-lower insulating layer 227 and the second peri-lower insulating layer 228, and the peri-wiring line 241b may extend horizontally (in a direction D1) in the first peri-lower insulating layer 227. The peri-contact plug 241a and the peri-wiring line 241b may be connected to the conductive patterns 223 and 225 of the peri-gate structure PG. Although not shown in the drawings, the peri-contact plug 241a and the peri-wiring line 241b may be connected to a source/drain region disposed on at least one side of the peri-gate structure PG.

Although the peri-contact plug 241a and the peri-wiring line 241b are shown as different layers, they are not limited thereto. A boundary between the peri-contact plug 241a and the peri-wiring line 241b may not be distinguished. Each of the peri-contact plug 241a and the peri-wiring line 241b includes a conductive material.

A first peri-upper insulating layer 261 and a second peri-upper insulating layer 262, stacked vertically on the first peri-upper insulating layer 261, may be disposed on the peri-contact plug 241a and the peri-wiring line 241b. The first peri-upper insulating layer 261 and the second peri-upper insulating layer 262 each include an insulating material. Unlike the illustrated example, an insulating layer formed of a single layer may be disposed on the peri-contact plug 241a and the peri-wiring line 241b.

A peri-connection structure 242a and 242b may be connected to the peri-wiring line 241b. The peri-connection structure 242a and 242b may include a peri-connection via 242a and a peri-connection line 242b. Each of the peri-connection via 242a and the peri-connection line 242b includes a conductive material.

Although the peri-connection via 242a and the peri-connection line 242b are shown as different layers, they are not limited thereto. The peri-connection structure 242a and 242b is shown as including one peri-connection line 242b disposed at one metal level, but this is merely for simplicity of description, and the present disclosure is not limited thereto. The peri-connection structure 242a and 242b may include a plurality of peri-connection lines 242b disposed at different metal levels, which may be arranged at different vertical levels (i.e., distances) relative to the upper surface of the substrate 100US.

A third peri-upper insulating layer 265 may be disposed on the peri-connection structure 242a and 242b. The third peri-upper insulating layer 265 includes an insulating material.

A shielding structure 171, SL, and 175 may be disposed above the substrate 100. For example, the shielding structure 171, SL, and 175 may be disposed on the peri-connection structure 242a and 242b.

The shielding structure 171, SL, and 175 may include the shielding conductive pattern SL and shielding insulating layers 171 and 175. The shielding insulating layers 171 and 175 may include a shielding insulating liner 171 and a shielding insulating capping layer 175.

The shielding conductive pattern SL may include a shielding conductive plate SLh and shielding conductive protrusion patterns SLp. The shielding conductive plate SLh may have a shape of a flat plate extending horizontally (i.e., in a first direction D1 and/or a second direction D2 parallel to the upper surface of the substrate 100US, the first direction D1 intersecting the second direction D2). The shielding conductive plate SLh may be disposed on the cell array region CAR. A part of the shielding conductive plate SLh may extend to the peripheral circuit region PCR.

The shielding conductive protrusion pattern SLp may protrude (i.e., extend) from the shielding conductive plate SLh in a third direction D3. For example, the third direction D3 may be a vertical direction perpendicular to the upper surface of the substrate 100US.

Each of the shielding conductive protrusion patterns SLp may protrude vertically toward the word lines WL1 and WL2. Each of the shielding conductive protrusion patterns SLp may extend in a second direction D2. The shielding conductive protrusion patterns SLp may be adjacent to one another in a first direction D1. For example, the first direction D1 and the second direction D2 may be horizontal directions that are parallel to the substrate 100.

The shielding insulating capping layer 175 may be disposed on the third peri-upper insulating layer 265. The shielding insulating capping layer 175 may be disposed between the third peri-upper insulating layer 265 and the shielding conductive pattern SL.

The shielding insulating liner 171 may be disposed on the shielding conductive pattern SL. The shielding insulating liner 171 may extend along the profiles (i.e., following a contour) of the shielding conductive plate SLh and the shielding conductive protrusion pattern SLp. The shielding insulating liner 171 does not extend along a sidewall of the shielding conductive pattern SL. The sidewall of the shielding conductive pattern SL may define a boundary of the shielding conductive pattern SL. The shielding conductive pattern SL may be disposed between the shielding insulating liner 171 and the shielding insulating capping layer 175.

A part of the shielding insulating liner 171 may extend along the top surface of a first upper insulating layer 263. The first upper insulating layer 263 may be disposed on the third peri-upper insulating layer 265. The first upper insulating layer 263 may cover the sidewall of the shielding insulating capping layer 175 and the sidewall of the shielding conductive pattern SL. The term “cover” (or “covering,” or like terms), as may be used herein, is intended to broadly refer to an element, structure or layer that is on or over another element, structure or layer, either directly or with one or more other intervening elements, structures or layers therebetween.

The shielding conductive pattern SL includes a conductive material. The shielding conductive pattern SL may include, for example, at least one of doped polysilicon, conductive metal nitride, conductive metal silicon nitride, metal carbonitride, conductive metal silicide, conductive metal oxide, a 2D material, or metal. The shielding insulating liner 171, the shielding insulating capping layer 175, and the first upper insulating layer 263 each include an insulating material. Depending on materials included in the shielding insulating liner 171 and the first upper insulating layer 263, a boundary between the shielding insulating liner 171 and the first upper insulating layer 263 may not be distinguished.

The bit lines BL may be disposed on the substrate 100. The bit lines BL may be disposed above the shielding conductive pattern SL. The bit line BL may be elongated (i.e., extend) in the second direction D2. Adjacent bit lines BL may be laterally spaced apart from each other in the first direction D1.

Each bit line BL may be disposed above the shielding conductive plate SLh. The bit line BL may be disposed between the shielding conductive protrusion patterns SLp adjacent in the first direction D1.

Each bit line BL may extend from the cell array region CAR to the peripheral circuit region PCR. The end of each bit line BL may be disposed on the peripheral circuit region PCR. A part of the bit line BL may overlap the cell region element isolation layer STI surrounding the cell array region CAR in the third direction D3.

The bit line BL may include a semiconductor pattern 161, a metal pattern 163, and a line mask pattern 165 that are sequentially stacked in the third direction D3 (i.e., vertically stacked). Unlike the illustrated example, the bit line BL may include one of the semiconductor pattern 161 and the metal pattern 163.

For example, the semiconductor pattern 161 may include a top surface BL_US of the bit line. When the bit line BL does not include the semiconductor pattern 161, the metal pattern 163 may include the top surface BL_US of the bit line.

The bit line BL may include a conductive bit line. The conductive bit line may be a layer containing a conductive material in the bit line BL. The conductive bit line may include the semiconductor pattern 161 and the metal pattern 163.

The semiconductor pattern 161 may include a conductive semiconductor material. The conductive semiconductor material may be, for example, a semiconductor material doped with impurities. The semiconductor pattern 161 may include at least one of polysilicon, polysilicon germanium, polygermanium, amorphous silicon, amorphous silicon germanium, or amorphous germanium, although embodiments are not limited thereto. The metal pattern 163 may include a conductive material including metal, although embodiments are not limited thereto. The metal pattern 163 may include, for example, at least one of doped polysilicon, conductive metal nitride, conductive metal silicon nitride, metal carbonitride, conductive metal silicide, conductive metal oxide, a 2D material, or metal, although embodiments are not limited thereto. The line mask pattern 165 may include an insulating material such as silicon nitride or silicon oxynitride, although embodiments are not limited thereto.

The cell region element isolation layer STI may be disposed above the first upper insulating layer 263. The shielding insulating liner 171 may be disposed between the cell region element isolation layer STI and the first upper insulating layer 263. In plan view, the cell region element isolation layer STI may define the cell array region CAR where the word lines WL1 and WL2, the back gate electrodes BG, the active patterns AP1 and AP2, and the like are disposed. Although it is illustrated that the cell region element isolation layer STI is a single layer, the present disclosure is not limited thereto. The cell region element isolation layer STI includes an insulating material.

The first active patterns AP1 and the second active patterns AP2 may be disposed on each bit line BL. The first active patterns AP1 and the second active patterns AP2 may be alternately disposed along the second direction D2.

The first active patterns AP1 may be spaced apart from each other in the first direction D1. The first active patterns AP1 may be spaced apart from each other at regular intervals. The second active patterns AP2 may be spaced apart from each other in the first direction D1. The second active patterns AP2 may be spaced apart from each other at regular intervals. The first active pattern AP1 may be spaced apart from the second active pattern AP2 in the second direction D2. The first active patterns AP1 and the second active patterns AP2 may be two-dimensionally arranged along the first and second directions D1 and D2 that intersect each other (i.e., in a horizontal plane).

For example, each of the first active pattern AP1 and the second active pattern AP2 may comprise a monocrystalline semiconductor material. In one example, each of the first active pattern AP1 and the second active pattern AP2 may be made of monocrystalline silicon.

Each of the first active pattern AP1 and the second active pattern AP2 may have a length in the first direction D1, a width in the second direction D2, and a height in the third direction D3. Each of the first active pattern AP1 and the second active pattern AP2 may have a substantially uniform width. That is, each of the first active pattern AP1 and the second active pattern AP2 may have substantially the same width on first and second surfaces S1 and S2, the second surface S2 being opposite the first surface S1 in a vertical direction. Further, the width of the first active pattern AP1 may be the same as the width of the second active pattern AP2.

The width of the first active pattern AP1 and the width of the second active pattern AP2 may be within a range of a few nanometers (nm) to tens of nm. For example, the width of the first active pattern AP1 and the width of the second active pattern AP2 may be about 1 nm to 30 nm, and more preferably about 1 nm to 10 nm, but is not limited thereto. The length of each of the first and second active patterns AP1 and AP2 may be greater than the line width of the bit line BL. That is, the length of each of the first and second active patterns AP1 and AP2 in the first direction D1 may be greater than the width of the bit line BL in the first direction D1.

Each of the first active pattern AP1 and the second active pattern AP2 includes a first surface S1 and a second surface S2 opposite to each other in the third direction D3. For example, the first surfaces S1 of the first and second active patterns AP1 and AP2 face the upper surface of the bit line BL_US. The second surfaces S2 of the first and second active patterns AP1 and AP2 face contact patterns BC.

The first surfaces S1 of the first and second active patterns AP1 and AP2 are connected to the bit line BL. The term “connected” (or “connecting,” “contact,” “contacting,” or like terms), as may be used herein, is intended to refer to a physical and/or electrical connection between two or more elements, and may include other intervening elements. As used herein, the term “and/or” includes any and all combinations of one or more of the associated listed items. For example, the first surfaces S1 of the first and second active patterns AP1 and AP2 may be connected to the semiconductor pattern 161 of the bit line BL. Unlike the illustrated example, when the semiconductor pattern 161 is omitted, the first surfaces S1 of the first and second active patterns AP1 and AP2 may be connected to the metal pattern 163. The second surfaces S2 of the first and second active patterns AP1 and AP2 may be connected to the contact patterns BC.

Each of the first active pattern AP1 and the second active pattern AP2 may include a first sidewall SS1 and a second sidewall SS2 opposite to each other in the second direction D2. The first sidewall SS1 of the first active pattern AP1 may face the second sidewall SS2 of the second active pattern AP2.

The second sidewall SS2 of the first active pattern AP1 may be adjacent to a first word line WL1. The first sidewall SS1 of the second active pattern AP2 may be adjacent to a second word line WL2.

Although not shown, in one example, each of the first active pattern AP1 and the second active pattern AP2 may include a first dopant region adjacent to the bit line BL and a second dopant region adjacent to the contact pattern BC. Each of the first active pattern AP1 and the second active pattern AP2 may include a channel region between the first dopant region and the second dopant region. The first dopant region and the second dopant region are regions formed by doping dopants into the first active pattern AP1 and the second active pattern AP2. Unlike the above description, each of the first active pattern AP1 and the second active pattern AP2 may not include at least one of the first dopant region or the second dopant region.

During the operation of the semiconductor memory device, the channel regions of the first and second active patterns AP1 and AP2 may be controlled by the first and second word lines WL1 and WL2 and the back gate electrodes BG. Since the first and second active patterns AP1 and AP2 are made of a monocrystalline semiconductor material, the leakage current characteristics of the semiconductor memory device may be improved.

In the semiconductor memory device according to some embodiments, boundary dummy active patterns AP_E may be disposed along the boundary of the cell array region CAR. For example, the boundary dummy active patterns AP_E may be in contact with the cell region element isolation layer STI.

The boundary dummy active patterns AP_E may be spaced apart from each other in the first direction D1. The boundary dummy active patterns AP_E may be arranged in the first direction D1. For example, the boundary dummy active pattern AP_E may not be connected to the data storage pattern DSP.

The back gate electrodes BG may be disposed above the bit line BL and the shielding conductive pattern SL. The back gate electrodes BG may be spaced apart from each other in the second direction D2. The back gate electrodes BG may be spaced apart from each other at regular intervals. Each of the back gate electrodes BG may extend in the first direction D1 across the bit line BL.

Each of the back gate electrodes BG may be disposed between the first active pattern AP1 and the second active pattern AP2 adjacent to each other in the second direction D2. The first active pattern AP1 and the second active pattern AP2 may be spaced apart from each other in the second direction D2 with the back gate electrode BG therebetween. In other words, the first active pattern AP1 may be disposed on one side of each of the back gate electrodes BG, and the second active pattern AP2 may be disposed on the other side of each of the back gate electrodes BG. The height of the back gate electrode BG in the third direction D3, relative to the upper surface of the substrate 100US being a base reference layer, may be smaller than the heights of the first and second active patterns AP1 and AP2 relative to the upper surface of the substrate 100US.

Each of the back gate electrodes BG may be disposed between the first sidewall SS1 of the first active pattern AP1 and the second sidewall SS2 of the second active pattern AP2. Each of the back gate electrodes BG may be disposed on the first sidewall SS1 of the first active pattern AP1 and the second sidewall SS2 of the second active pattern AP2.

The first active patterns AP1 may be disposed between the first word line WL1 and the back gate electrode BG. The second active patterns AP2 may be disposed between the second word line WL2 and the back gate electrode BG. A pair of the first word line WL1 and the second word line WL2 may be disposed between adjacent back gate electrodes BG in the second direction D2.

The back gate electrode BG may include a first surface BG_S1 and a second surface BG_S2 opposite to each other in the third direction D3. The first surface BG_S1 of the back gate electrode is closer to the bit line BL than the second surface BG_S2 of the back gate electrode. The first surface BG_S1 of the back gate electrode may face the bit line BL.

The back gate electrode BG may include a conductive material, and may include, for example, at least one of a conductive semiconductor material, conductive metal nitride, conductive metal silicon nitride, metal carbonitride, conductive metal silicide, conductive metal oxide, a 2D material, or metal, although embodiments are not limited thereto.

During the operation of the semiconductor memory device, a voltage may be applied to the back gate electrode BG to adjust the threshold voltage of a vertical channel transistor. By adjusting the threshold voltage of the vertical channel transistor, the deterioration of the leakage current characteristics may be prevented or at least reduced.

A back gate isolation pattern 111 may be disposed between the first active pattern AP1 and the second active pattern AP2 adjacent in the second direction D2. The back gate isolation pattern 111 may extend in the first direction D1 to be disposed side by side with the back gate electrode BG. The back gate isolation pattern 111 may be disposed on the second surface BG_S2 of the back gate electrode.

The back gate isolation pattern 111 may include, for example, a silicon oxide layer, a silicon oxynitride layer, or a silicon nitride layer. For example, the back gate isolation pattern 111 may be formed at the same level as a gate capping pattern 143 to be described later. Here, the term “same level” means that they are formed by the same fabricating process (i.e., in a same fabrication step). The back gate isolation pattern 111 may comprise the same material as that of the gate capping pattern 143.

A back gate insulating pattern 113 may be disposed between the back gate electrode BG and the first active pattern AP1, and between the back gate electrode BG and the second active pattern AP2 adjacent in the second direction D2. The back gate insulating pattern 113 may be disposed between the back gate isolation pattern 111 and the first active pattern AP1, and between the back gate isolation pattern 111 and the second active pattern AP2. The back gate insulating pattern 113 may include, for example, a silicon oxide layer, a silicon oxynitride layer, a high-k insulating layer having a dielectric constant higher than that of the silicon oxide layer, or a combination thereof, although embodiments are not limited thereto.

A back gate capping pattern 115 may be disposed between the bit line BL and the back gate electrode BG. The back gate capping pattern 115 may be disposed between the first active pattern AP1 and the second active pattern AP2 adjacent in the second direction D2. The back gate capping pattern 115 may extend in the first direction D1 to be disposed side by side with the back gate electrode BG. The back gate capping pattern 115 may be disposed on the first surface BG_S1 of the back gate electrode.

The back gate capping pattern 115 may comprise an insulating material. The back gate capping pattern 115 may include, for example, at least one of a silicon oxide layer, a silicon oxynitride layer, or a silicon nitride layer.

The first word line WL1 and the second word line WL2 may be disposed above the bit line BL and the shielding conductive pattern SL. The first word line WL1 and the second word line WL2 may be disposed above the shielding conductive protrusion pattern SLp.

Each of the first word line WL1 and the second word line WL2 may extend in the first direction D1. The first word line WL1 and the second word line WL2 may be alternately arranged in the second direction D2.

The first word line WL1 may be disposed on the second sidewall SS2 of the first active patterns AP1. The second word line WL2 may be disposed on the first sidewall SS1 of the second active patterns AP2. The first active patterns AP1 and the second active patterns AP2 may be disposed between the first word line WL1 and the second word line WL2 adjacent in the second direction D2.

The first word line WL1 and the second word line WL2 may be spaced apart vertically from the bit line BL and the contact pattern BC in the third direction D3. The first word line WL1 and the second word line WL2 may be disposed between the bit line BL and the contact pattern BC.

Each of the first word line WL1 and the second word line WL2 may have a width in the second direction D2. The width of the first word line WL1 and the width of the second word line WL2 above the bit line BL may be different from the width of the first word line WL1 and the width of the second word line WL2 above the shielding conductive pattern SL.

For example, each of the first word line WL1 and the second word line WL2 may include a first portion WLa of the word line and a second portion WLb of the word line. The width of the first portion WLa of the word line in the second direction D2 may be smaller than the width of the second portion WLb of the word line in the second direction D2. In one example, the first portion WLa of the word line may overlap the bit line BL in the third direction D3. The second portion WLb of the word line may overlap the shielding conductive line SL in the third direction D3. The term “overlap” (or “overlapping,” or like terms), as may be used herein, is intended to broadly refer to a first element that intersects with at least a portion of a second element in the vertical direction (i.e., the third direction D3), but does not require that the first and second elements be completely aligned with one another in a horizontal plane (i.e., in the first direction D1 and/or the second direction D2).

Each of the first word line WL1 and the second word line WL2 may include the first portion WLa of the word line and the second portion WLb of the word line that are alternately disposed along the first direction D1. In the first word line WL1, each of the first active patterns AP1 may be disposed between the second portions WLb of the word lines adjacent in the first direction D1. In the second word line WL2, each of the second active patterns AP2 may be disposed between the second portions WLb of the word lines adjacent in the first direction D1.

Each of the first word line WL1 and the second word line WL2 may include a first surface WL_S1 and a second surface WL_S2 opposite to each other in the third direction D3. The first surface WL_S1 of the first and second word lines WL1, WL2 is closer to the bit line BL than the second surface WL_S2 of the first and second word lines.

The second word line WL2 will be described as an example. In one example, a height H2 of the second word line WL2 in the third direction D3 (between the first surface WL_S1 and the second surface WL_S2) may be the same as the height of the back gate electrode BG in the third direction D3 (between the first surface BG_S1 and the second surface BG_S2). In another example, the height H2 of the second word line WL2 in the third direction D3 may be greater than the height of the back gate electrode BG in the third direction D3. In yet another example, the height H2 of the second word line WL2 in the third direction D3 may be smaller than the height of the back gate electrode BG in the third direction D3.

Further, in one example, with respect to the top surface BL_US of the bit line, the height of the first surface WL_S1 of the second word line may be the same as the height of the first surface BG_S1 of the back gate electrode. In another example, the first surface WL_S1 of the second word line may be higher than the first surface BG_S1 of the back gate electrode. In yet another example, the first surface WL_S1 of the second word line may be lower than the first surface BG_S1 of the back gate electrode.

Furthermore, in one example, with respect to the top surface BL_US of the bit line, the height of the second surface WL_S2 of the second word line may be the same as the height of the second surface BG_S2 of the back gate electrode. In another example, the second surface WL_S2 of the second word line may be higher than the second surface BG_S2 of the back gate electrode. In still another example, the second surface WL_S2 of the second word line may be lower than the second surface BG_S2 of the back gate electrode.

The first word line WL1 and the second word line WL2 include a conductive material. The first word line WL1 and the second word line WL2 may include, for example, at least one of a conductive semiconductor material, conductive metal nitride, conductive metal silicon nitride, metal carbonitride, conductive metal silicide, conductive metal oxide, a 2D material, or metal, although embodiments are not limited thereto. Although the first word line WL1 and the second word line WL2 are each illustrated as a single conductive layer, this is merely for simplicity of description and the present disclosure is not limited thereto.

For example, the first surfaces WL_S1 of the first and second word lines WL1 and WL2 may be flat. The second surfaces WL_S2 of the first and second word lines WL1 and WL2 may be flat.

A dummy word line WL_D may extend along the boundary of the cell array region CAR. The dummy word line WL_D may extend along the cell region element isolation layer STI. The dummy word line WL_D may extend in the first direction D1. The dummy word line WL_D may be spaced apart from the first and second word lines WL1 and WL2 in the second direction D2.

The boundary dummy active patterns AP_E may be disposed between the dummy word line WL_D and the cell region element isolation layer STI. The dummy word line WL_D may be similar in shape to the first word line WL1 and the second word line WL2. The dummy word line WL_D may be formed at the same level as the first and second word lines WL1 and WL2 relative to the upper surface of the substrate 100US being a base reference layer.

The gate capping pattern 143 may be disposed between the first word line WL1 and the contact pattern BC, and between the second word line WL2 and the contact pattern BC. The gate capping pattern 143 may cover the second surfaces WL_S2 of the first and second word lines WL1 and WL2.

In cross-sectional view, the gate capping pattern 143 between the first word line WL1 and the contact pattern BC may be spaced apart in the second direction D2 from the gate capping pattern 143 between the second word line WL2 and the contact pattern BC. The gate capping pattern 143 between the first word line WL1 and the contact pattern BC may be separated from the gate capping pattern 143 between the second word line WL2 and the contact pattern BC by the back gate isolation pattern 111.

A gate shielding pattern 144 may be disposed between the first word line WL1 and the bit line BL, and between the second word line WL2 and the bit line BL. The gate shielding pattern 144 may cover the first surfaces WL_S1 of the first and second word lines WL1 and WL2.

In a cross-section of the first portion WLa of the word line, the gate shielding pattern 144 between the first word line WL1 and the bit line BL may be separated from the gate shielding pattern 144 between the second word line WL2 and the bit line BL by the active patterns AP1 and AP2. In a cross-section of the second portion WLb of the word line, the gate shielding pattern 144 may cover the first surface WL_S1 of the first word line WL1 and the first surface WL_S1 of the second word line WL2 together.

The gate capping pattern 143 and the gate shielding pattern 144 may each be formed of an insulating material. The gate capping pattern 143 and the gate shielding pattern 144 may each include, for example, one of a silicon oxide layer, a silicon oxynitride layer, and a silicon nitride layer.

Gate insulating patterns GOX may be disposed between the first word line WL1 and the first active pattern AP1, and between the second word line WL2 and the second active pattern AP2. The gate insulating patterns GOX may extend in the first direction D1 to be disposed side by side with the first word line WL1 and the second word line WL2. The gate insulating patterns GOX may be disposed between the dummy word line WL_D and the boundary dummy active pattern AP_E.

Each of the gate insulating patterns GOX may include a silicon oxide layer, a silicon oxynitride layer, a high-k insulating layer having a dielectric constant higher than that of the silicon oxide layer, or a combination thereof, although embodiments are not limited thereto.

The gate insulating patterns GOX may extend along the second sidewall SS2 of the first active pattern AP1, and may extend along the first sidewall SS1 of the second active pattern AP2. In cross-sectional view, the gate insulating pattern GOX between the first active pattern AP1 and the first word line WL1 may be laterally separated from the gate insulating pattern GOX between the second active pattern AP2 and the second word line WL2.

The gate isolation pattern GSS and the outermost gate isolation pattern GSS_E may be disposed on the bit line BL. The gate isolation pattern GSS and the outermost gate isolation pattern GSS_E may be disposed above the shielding conductive pattern SL.

The gate isolation pattern GSS and the outermost gate isolation pattern GSS_E may be disposed vertically (i.e., in the third direction D3) between the bit line BL and the data storage pattern DSP. The gate isolation pattern GSS and the outermost gate isolation pattern GSS_E may each be in contact with the bit line BL.

The gate isolation pattern GSS may be disposed between the first word line WL1 and the second word line WL2 adjacent in the second direction D2. The first word line WL1 and the second word line WL2 may be separated by the gate isolation pattern GSS. The gate isolation pattern GSS may extend in the first direction D1 between the first word line WL1 and the second word line WL2.

The first word line WL1 may be disposed between the gate isolation pattern GSS and the first active pattern AP1. The gate isolation pattern GSS may be disposed on the second sidewall SS2 of the first active pattern AP1. The second word line WL2 may be disposed between the gate isolation pattern GSS and the second active pattern AP2. The gate isolation pattern GSS may be disposed on the first sidewall SS1 of the second active pattern AP2.

The gate capping pattern 143 and the gate shielding pattern 144 may be disposed between the gate isolation pattern GSS and the first active pattern AP1. The gate capping pattern 143 and the gate shielding pattern 144 may be disposed between the gate isolation pattern GSS and the second active pattern AP2.

The gate isolation pattern GSS may include an isolation low-k pattern 153. The isolation low-k pattern 153 may extend in the first direction D1 along the first and second word lines WL1 and WL2. In the semiconductor memory device according to some embodiments, the gate isolation pattern GSS may include one isolation low-k pattern 153.

The isolation low-k pattern 153 may include a gate isolation air gap 153AG. For example, the isolation low-k pattern 153 may be the gate isolation air gap 153AG. In the semiconductor memory device according to some embodiments, the gate isolation air gap 153AG may not be in contact with the bit line BL. The gate isolation air gap 153AG may not be in contact with the conductive bit lines 161 and 163.

The second word line WL2 will be described as an example. A height H1 of the isolation low-k pattern 153 in the third direction D3 may be greater than the height H2 of the second word line WL2 in the third direction D3. A separation distance H21 between the bit line BL and the second word line WL2 (i.e., between the top surface BL_US of the bit line and the first surface WL_S1 of the second word line WL2) in the third direction D3 may be greater than a separation distance H11 between the bit line BL and the isolation low-k pattern 153 in the third direction D3. The distances by which the second word line WL2 and the isolation low-k pattern 153 are spaced apart from the bit line BL may be measured with respect to the top surface BL_US of the bit line. A part of the isolation low-k pattern 153 may protrude in the third direction D3 toward the bit line BL beyond the first surface WL_S1 of the second word line WL2.

In FIGS. 4 and 5, a separation distance between the data storage pattern DSP and the second word line WL2 in the third direction D3 may be greater than a separation distance between the data storage pattern DSP and the isolation low-k pattern 153 in the third direction D3. Another part of the isolation low-k pattern 153 may protrude in the third direction D3 toward the data storage pattern DSP beyond the second surface WL_S2 of the second word line WL2.

The gate isolation pattern GSS may further include a gate isolation spacer 151. The gate isolation spacer 151 may be disposed on both sides (i.e., opposing sidewalls) of the isolation low-k pattern 153. The gate isolation spacers 151 may be in contact with the first word line WL1 and the second word line WL2. The gate isolation spacers 151 may be in contact with the top surface BL_US of the bit line. Each of the gate isolation spacers 151 may extend in the first direction D1 along the isolation low-k pattern 153.

The gate isolation pattern GSS may further include a low-k capping pattern 155. The low-k capping pattern 155 may be disposed above and below the isolation low-k pattern 153. For example, the low-k capping pattern 155 may include a lower low-k capping pattern in contact with the top surface BL_US of the bit line, and an upper low-k capping pattern adjacent to the data storage pattern DSP. The low-k capping pattern 155 may be disposed between the gate isolation spacers 151; sidewalls of the low-k capping pattern 155 and sidewalls of the isolation low-k pattern 153 may be coplanar.

The gate isolation spacer 151 and the low-k capping pattern 155 may each include one of a silicon oxide layer, a silicon nitride layer, and a silicon oxynitride layer. In one example, the lower low-k capping pattern and the upper low-k capping pattern may include different materials. In another example, the lower low-k capping pattern and the upper low-k capping pattern may include the same material.

The outermost gate isolation pattern GSS_E may be disposed between the cell region element isolation layer STI and the word lines WL1 and WL2 disposed at the outermost portion of the cell array region CAR. The outermost gate isolation pattern GSS_E may extend in the first direction D1 along the boundary of the cell array region CAR. The outermost gate isolation pattern GSS_E may extend along both boundaries of the cell array region CAR extending in the first direction D1. The word lines WL1 and WL2, the back gate electrodes BG, the active patterns AP1 and AP2, and the gate isolation patterns GSS may be disposed between the outermost gate isolation patterns spaced apart in the second direction D2.

The outermost gate isolation pattern GSS_E may be disposed between the first word line WL1 and the dummy word line WL_D adjacent in the second direction D2. Although not shown, the outermost gate isolation pattern GSS_E may be disposed between the second word line WL2 and the dummy word line WL_D adjacent in the second direction D2.

The first word line WL1 disposed at the outermost portion of the cell array region CAR may be disposed between the outermost gate isolation pattern GSS_E and the back gate electrode BG disposed at the outermost portion of the cell array region CAR. Although not shown in the drawings, the second word line WL2 disposed at the outermost portion of the cell array region CAR may be disposed between the outermost gate isolation pattern GSS_E and the back gate electrode BG disposed at the outermost portion of the cell array region CAR.

The outermost gate isolation pattern GSS_E may include an outermost isolation low-k pattern 153E. The outermost isolation low-k pattern 153E may extend in the first direction D1. In the semiconductor memory device according to some embodiments, the outermost gate isolation pattern GSS_E may include a plurality of outermost isolation low-k patterns 153E. The number of the outermost isolation low-k patterns 153E included in the outermost gate isolation pattern GSS_E may be greater than the number of the isolation low-k patterns 153 included in the gate isolation pattern GSS.

The outermost isolation low-k pattern 153E may include an outermost gate isolation air gap 153AG_E. For example, the outermost isolation low-k pattern 153E may be the outermost gate isolation air gap 153AG_E. For example, the outermost gate isolation air gap 153AG_E may not be in contact with the bit line BL.

The outermost gate isolation pattern GSS_E may further include an outermost gate isolation spacer 151E. The outermost gate isolation spacer 151E may be disposed on both sides (i.e., opposing sidewalls) of the outermost isolation low-k pattern 153E. Each of the outermost gate isolation spacers 151E may extend in the first direction D1 along the outermost isolation low-k pattern 153E.

The outermost gate isolation spacer 151E may include one of a silicon oxide layer, a silicon nitride layer, and a silicon oxynitride layer. Each of the plurality of outermost gate isolation spacers 151E may include the same material. For example, the outermost gate isolation spacer 151E may include the same material as the gate isolation spacer 151. When the outermost gate isolation pattern GSS_E includes an odd number of the outermost gate isolation spacers 151E, the outermost gate isolation spacer 151E located in the center may include a different material from the outermost gate isolation spacers 151E adjacent to the first word line WL1 and the dummy word line WL_D. Taking the first word line WL1 as an example, an insulating material included in the outermost gate isolation spacer 151E between the first word line WL1 and the outermost isolation low-k pattern 153E may be different from an insulating material included in the outermost gate isolation spacer 151E between the outermost isolation low-k patterns 153E.

The outermost gate isolation pattern GSS_E may further include an outermost low-k capping pattern 155E. The outermost low-k capping pattern 155E may be disposed above and below the outermost isolation low-k pattern 153E. For example, the outermost low-k capping pattern 155E may include an outermost lower low-k capping pattern in contact with the top surface BL_US of the bit line, and an outermost upper low-k capping pattern adjacent to the data storage pattern DSP. The outermost lower low-k capping pattern includes the same material as the lower low-k capping pattern. The outermost upper low-k capping pattern includes the same material as the upper low-k capping pattern.

The width of the gate isolation pattern GSS in the second direction D2 may be different from the width of the outermost gate isolation pattern GSS_E in the second direction D2. For example, the width of the gate isolation pattern GSS in the second direction D2 is smaller than that of the outermost gate isolation pattern GSS_E in the second direction D2 in one or more embodiments.

Since the gate isolation pattern GSS includes the low-k capping pattern 155, a coupling phenomenon between the first word line WL1 and the second word line WL2 facing each other (i.e., adjacent to one another) may be reduced. As a result, performance and reliability of the semiconductor memory device may be improved.

The contact patterns BC may penetrate (i.e., extend into) a contact interlayer insulating layer 231. The contact patterns BC may be respectively connected to the first active pattern AP1 and the second active pattern AP2. The contact patterns BC may be connected to the second surface S2 of the first and second active patterns AP1 and AP2. In plan view, the contact patterns BC may have various shapes such as, for example, a circle, an ellipse, a rectangle, a square, a rhombus, and a hexagon. The contact interlayer insulating layer 231 may be disposed on the cell region element isolation layer STI.

The contact patterns BC may include a conductive material. The contact pattern BC may include, for example, at least one of a conductive semiconductor material, conductive metal nitride, conductive metal silicon nitride, metal carbonitride, conductive metal silicide, conductive metal oxide, a 2D material, or metal. The contact interlayer insulating layer 231 includes an insulating material.

Landing pads LP may be disposed on the contact patterns BC. In plan view (see FIG. 2), the landing pads LP may have various shapes such as, for example, a circle, an ellipse, a rectangle, a square, a rhombus, and a hexagon, although embodiments are not limited thereto.

A pad isolation insulating layer 245 may be disposed on the contact interlayer insulating layer 231. The pad isolation insulating layer 245 may be disposed between the landing pads LP adjacent to one another. The pad isolation insulating layer 245 may separate the landing pads LP. In plan view, the landing pads LP may be arranged in a matrix form along the first direction D1 and the second direction D2. The top surface of the landing pad LP may be substantially coplanar with the top surface of the pad isolation insulating layer 245.

The landing pad LP may include a conductive material, and may include, for example, at least one of a conductive semiconductor material, conductive metal nitride, conductive metal silicon nitride, metal carbonitride, conductive metal silicide, conductive metal oxide, a 2D material, or metal. The pad isolation insulating layer 245 includes an insulating material.

A bit line contact plug 281 may be connected to the bit line BL. The bit line contact plug 281 may be disposed in (i.e., extending into and/or at least partially through) the contact interlayer insulating layer 231 and the cell region element isolation layer STI. The bit line contact plug 281 is electrically connected to a conductive bit line.

An upper connection line 282 may be disposed in the pad isolation insulating layer 245. The upper connection line 282 may be electrically connected to the bit line contact plug 281.

An upper peripheral contact plug 283 may be connected to the peri-connection line 242b. The upper peripheral contact plug 283 may extend into and/or at least partially through the contact interlayer insulating layer 231, the cell region element isolation layer STI, and the first upper insulating layer 263. The upper peripheral contact plug 283 may connect the bit line BL to the peri-connection line 242b. The bit line contact plug 281, the upper connection line 282, and the upper peripheral contact plug 283 each include a conductive material.

Although not shown in the drawings, the word lines WL1 and WL2, the back gate electrode BG, and the shielding conductive pattern SL may also be connected to the peri-connection line 242b.

The data storage patterns DSP may be respectively disposed on the landing pads LP. The data storage patterns DSP may be respectively electrically connected to the first and second active patterns AP1 and AP2. As shown in FIG. 2, the data storage patterns DSP may be arranged in a matrix form along the first direction D1 and the second direction D2. The data storage patterns DSP may completely overlap or partially overlap the landing pads LP in the third direction D3. The data storage patterns DSP may be in contact with all or part of the top surfaces of the landing pads LP.

In one example, the data storage patterns DSP may be capacitors. The data storage patterns DSP may include a capacitor dielectric layer 253 interposed between storage electrodes 251 and a plate electrode 255. The storage electrode 251 may be in contact with the landing pad LP. In plan view (see FIG. 2), the storage electrode 251 may have various shapes, such as a circle, an ellipse, a rectangle, a square, a rhombus, a hexagon, and the like. The storage electrodes 251 may penetrate (i.e., extend into and/or at least partially through) an upper etch stop layer 247. The upper etch stop layer 247 may be disposed on the pad isolation insulating layer 245. The upper etch stop layer 247 may be made of an insulating material.

The plate electrode 255 may include a lower plate electrode 255a and an upper plate electrode 255b. Unlike the illustrated example, the plate electrode 255 may be a single layer. Each of the storage electrode 251 and the plate electrode 255 may include a conductive material, and may include, for example, at least one of a conductive semiconductor material, conductive metal nitride, conductive metal silicon nitride, metal carbonitride, conductive metal silicide, conductive metal oxide, a 2D material, or metal, although embodiments are not limited thereto. The capacitor dielectric layer 253 may include at least one of a ferroelectric material, an antiferroelectric material, or a paraelectric material. For example, it may include one of a ferroelectric material, an antiferroelectric material, a paraelectric material, a combination of a ferroelectric material and an antiferroelectric material, a combination of a ferroelectric material and a paraelectric material, a combination of a paraelectric material and an antiferroelectric material, and a combination of a ferroelectric material, an antiferroelectric material, and a paraelectric material, although embodiments are not limited thereto.

On the other hand, the data storage patterns DSP may be variable resistance patterns that can be switched into two resistance states by an electrical pulse applied to a memory element. For example, the data storage patterns DSP may include a phase-change material whose crystalline state changes depending on the amount of current, perovskite compounds, transition metal oxide, magnetic materials, ferromagnetic materials, or antiferromagnetic materials, although embodiments are not limited thereto.

A second upper insulating layer 271 may be disposed above the upper etch stop layer 247. The second upper insulating layer 271 may be disposed on the data storage pattern DSP. For example, the second upper insulating layer 271 may cover the data storage pattern DSP. The second upper insulating layer 271 may surround (i.e., extend at least partially around) the sidewall of the plate electrode 255. The second upper insulating layer 271 includes an insulating material.

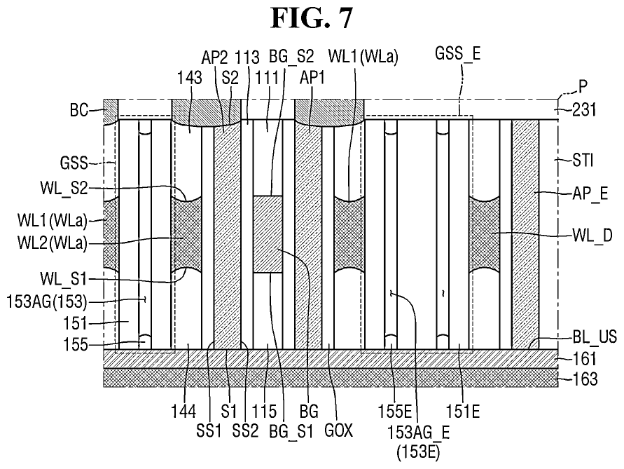

FIGS. 7 to 16 are cross-sectional views each illustrating an example semiconductor memory device according to embodiments of the present disclosure. For simplicity of description, the following description will focus on differences from the description with reference to FIGS. 1 to 6. For reference, FIGS. 7 to 16 are enlarged views of region P of the example semiconductor memory device shown in FIG. 4.

Referring to FIG. 7, in the semiconductor memory device according to some embodiments, the first surfaces WL_S1 of the first and second word lines WL1 and WL2 may be concave downward curved surfaces, such that edge portions of the first surface WL_S1, which are coplanar with sidewalls of the first and second word lines WL1 and WL2, are closer to the top surface BL_US of the bit line than a center portion of the first surface WL_S1.

The second surfaces WL_S2 of the first and second word lines WL1 and WL2 may be concave upward curved surfaces, such that edge portions of the second surface WL_S2, which are coplanar with sidewalls of the first and second word lines WL1 and WL2, are farther from the top surface BL_US of the bit line than a center portion of the second surface WL_S2.

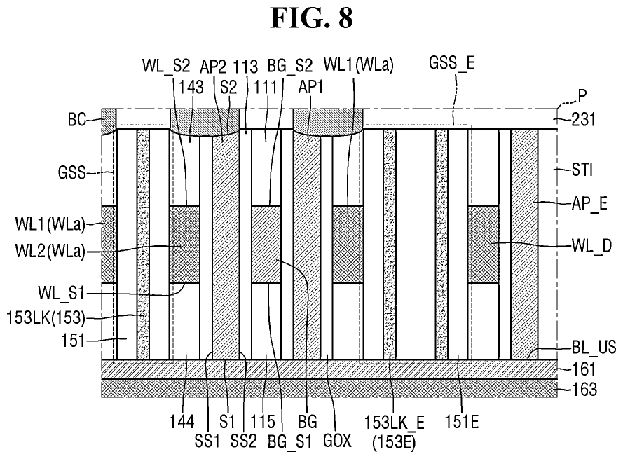

Referring to FIGS. 8 to 10, in the semiconductor memory device according to some embodiments, the isolation low-k pattern 153 may be formed of a gate isolation low-k material 153LK.

For example, the dielectric constant of the gate isolation low-k material 153LK is smaller than that of silicon oxide.

The gate isolation pattern GSS may not include the low-k capping pattern 155 (see FIG. 5). The gate isolation low-k material 153LK may be in contact with the bit line BL. For example, the gate isolation low-k material 153LK may be in contact with the conductive bit lines 161 and 163.

Unlike the illustrated example, in one example, the low-k capping pattern 155 (see FIG. 5) may be disposed between the gate isolation low-k material 153LK and the bit line BL. In another example, the low-k capping pattern 155 (see FIG. 5) may be disposed between the gate isolation low-k material 153LK and the contact interlayer insulating layer 231. In still another example, the low-k capping pattern 155 (see FIG. 5) may be disposed above and below the gate isolation low-k material 153LK.

The outermost isolation low-k pattern 153E may be formed of an outermost gate isolation low-k material 153LK_E. The outermost gate isolation low-k material 153LK_E may be the same material as the gate isolation low-k material 153LK. For example, the outermost gate isolation low-k material 153LK_E may be in contact with the conductive bit lines 161 and 163.

In FIG. 8, the outermost gate isolation pattern GSS_E may include a plurality of outermost gate isolation low-k materials 153LK_E laterally separated from each other. Adjacent outermost gate isolation low-k materials 153LK_E may be laterally separated by the outermost gate isolation spacer 151E. Each of the outermost gate isolation low-k materials 153LK_E may have a line shape extending in the third direction D3.

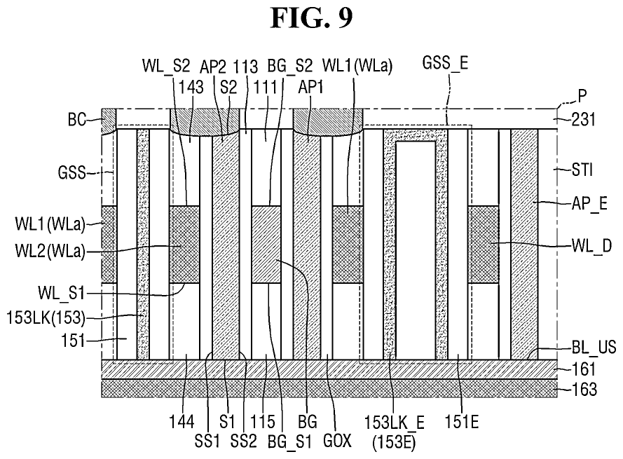

In FIG. 9, the outermost gate isolation pattern GSS_E may include one outermost gate isolation low-k material 153LK_E. The outermost gate isolation low-k material 153LK_E may have a “U” shape rotated 180 degrees (i.e., upside down, with its open end facing downward toward the bit line). The outermost gate isolation low-k material 153LK_E may include a vertical portion extending in the third direction D3 and a horizontal portion extending in the second direction D2. The vertical portion of the outermost gate isolation low-k material 153LK_E may be directly connected to the horizontal portion of the outermost gate isolation low-k material 153LK_E. The horizontal portion of the outermost gate isolation low-k material 153LK_E may extend horizontally along the contact interlayer insulating layer 231.

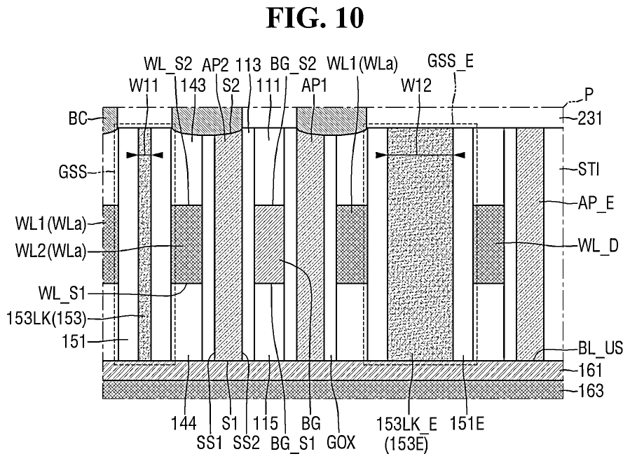

In FIG. 10, the outermost gate isolation pattern GSS_E may include the outermost gate isolation low-k material 153LK_E having a line shape extending in the third direction D3. The outermost gate isolation pattern GSS_E may include one outermost gate isolation low-k material 153LK_E. A width W12 of the outermost gate isolation low-k material 153LK_E in the second direction D2 is greater than a width W11 of the gate isolation low-k material 153LK in the second direction D2.

For example, the width of the outermost gate isolation spacer 151E in the second direction D2 may be the same as the width of the gate isolation spacer 151 in the second direction D2.

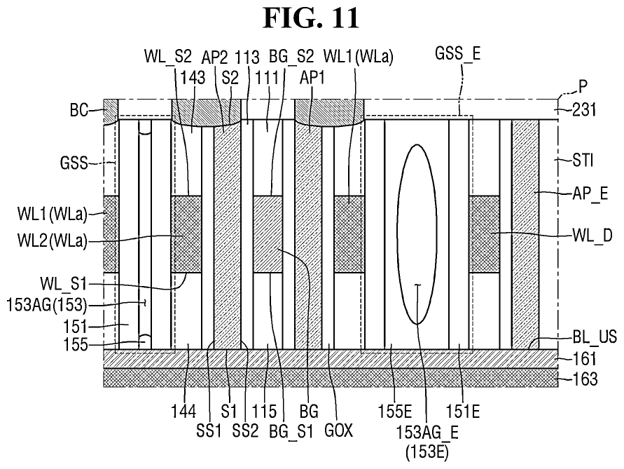

Referring to FIG. 11, in the semiconductor memory device according to some embodiments, the outermost gate isolation pattern GSS_E may include one outermost gate isolation air gap 153AG_E.

The outermost gate isolation air gap 153AG_E may be surrounded by the outermost low-k capping pattern 155E. In other words, the outermost gate isolation air gap 153AG_E may be disposed in the outermost low-k capping pattern 155E.

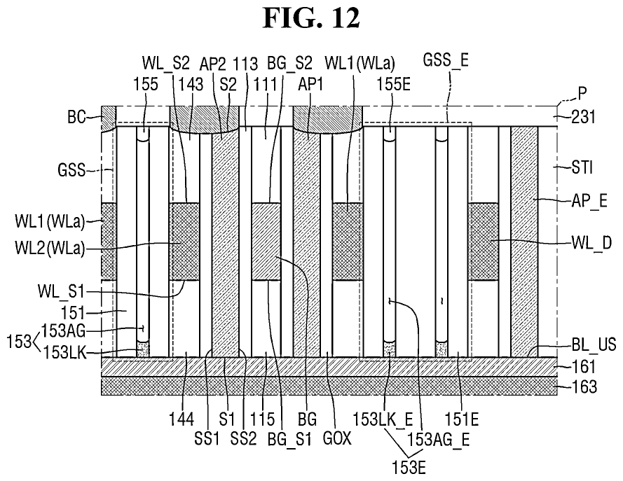

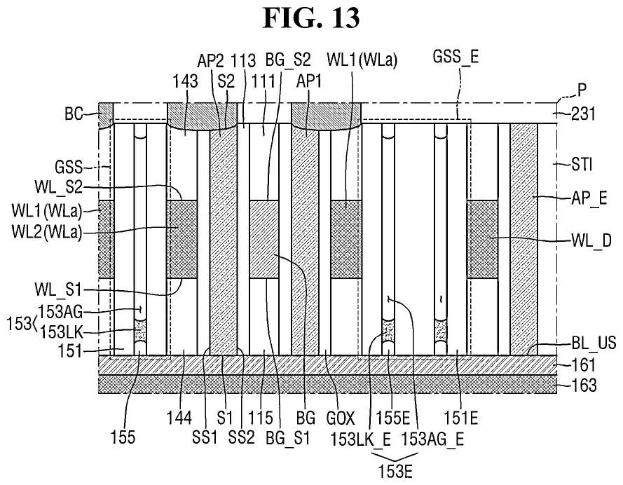

Referring to FIGS. 12 and 13, in the semiconductor memory device according to some embodiments, the isolation low-k pattern 153 may include the gate isolation air gap 153AG and the gate isolation low-k material 153LK.

The gate isolation low-k material 153LK may be disposed between the gate isolation air gap 153AG and the bit line BL. The gate isolation low-k material 153LK may be a lower isolation low-k pattern. The gate isolation air gap 153AG may be an upper isolation low-k pattern.

The outermost isolation low-k pattern 153E may include the outermost gate isolation air gap 153AG_E and the outermost gate isolation low-k material 153LK_E. The outermost gate isolation low-k material 153LK_E may be disposed between the outermost gate isolation air gap 153AG_E and the bit line BL.

The outermost gate isolation low-k material 153LK_E may be an outermost lower isolation low-k pattern. The outermost gate isolation air gap 153AG_E may be an outermost upper isolation low-k pattern.

The dielectric constant of the gate isolation low-k material 153LK and the dielectric constant of the outermost gate isolation low-k material 153LK_E are smaller than the dielectric constant of silicon oxide.

The low-k capping pattern 155 may be disposed between the isolation low-k pattern 153 and the capping interlayer insulating layer 231. The outermost low-k capping pattern 155E may be disposed between the outermost isolation low-k pattern 153E and the capping interlayer insulating layer 231.

In FIG. 12, the isolation low-k pattern 153 and the outermost isolation low-k pattern 153E may be in contact with the bit line BL. For example, the gate isolation low-k material 153LK and the outermost gate isolation low-k material 153LK_E may be in contact with the top surface BL_US of the bit line.

In FIG. 13, the isolation low-k pattern 153 and the outermost isolation low-k pattern 153E may not be in contact with the bit line BL. The low-k capping pattern 155 may be disposed between the isolation low-k pattern 153 and the bit line BL. The outermost low-k capping pattern 155E may be disposed between the outermost isolation low-k capping pattern 153E and the bit line BL.

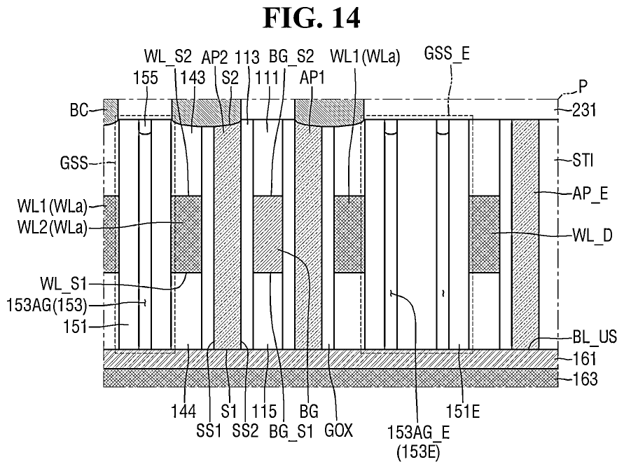

Referring to FIG. 14, in the semiconductor memory device according to some embodiments, the gate isolation air gap 153AG may be in contact with the bit line BL.

The outermost gate isolation air gap 153AG_E may be in contact with the bit line BL. The low-k capping pattern 155 may not be disposed between the gate isolation air gap 153AG and the bit line BL. The outermost low-k capping pattern 155E may not be disposed between the outermost gate isolation air gap 153AG_E and the bit line BL.

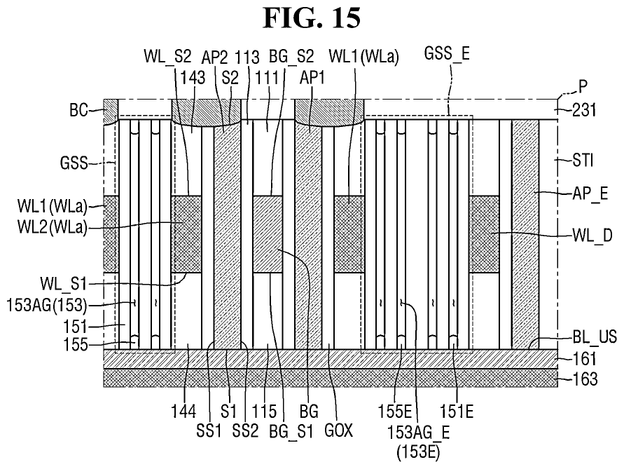

Referring to FIG. 15, in the semiconductor memory device according to some embodiments, the gate isolation pattern GSS may include a plurality of isolation low-k patterns 153.

For example, the gate isolation pattern GSS may include a plurality of gate isolation air gaps 153AG. The gate isolation air gaps 153AG may be laterally separated (in the second direction D2) by the gate isolation spacer 151.

Similarly, the outermost gate isolation pattern GSS_E may include a plurality of gate isolation air gaps 153AG. The number of the outermost gate isolation air gaps 153AG_E included in the outermost gate isolation pattern GSS_E may be greater than the number of the gate isolation air gaps 153AG included in the gate isolation pattern GSS.

Unlike the illustrated example, each isolation low-k pattern 153 included in the gate isolation pattern GSS may be the same as one of the isolation low-k patterns 153 described with reference to FIGS. 8 and 12 to 14.

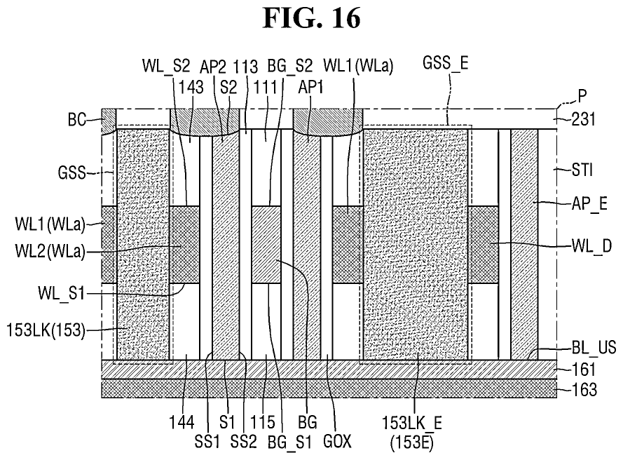

Referring to FIG. 16, in the semiconductor memory device according to some embodiments, the gate isolation pattern GSS may not include the gate isolation spacer 151 (see FIG. 14).

The isolation low-k pattern 153 may be in contact with the first word line WL1 and the second word line WL2. The isolation low-k pattern 153 may be formed of the gate isolation low-k material 153LK.

The outermost gate isolation pattern GSS_E may not include the outermost gate isolation spacer 151E (see FIG. 14). The outermost isolation low-k pattern 153E may be in contact with the first word line WL1 and the dummy word line WL_D. The outermost isolation low-k pattern 153E may be formed of the outermost gate isolation low-k material 153LK_E. Although not shown in the drawing, the outermost isolation low-k pattern 153E may be in contact with the second word line WL2 and the dummy word line WL_D.

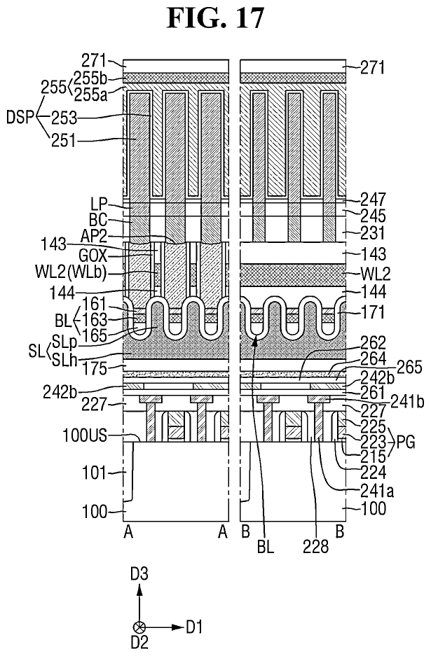

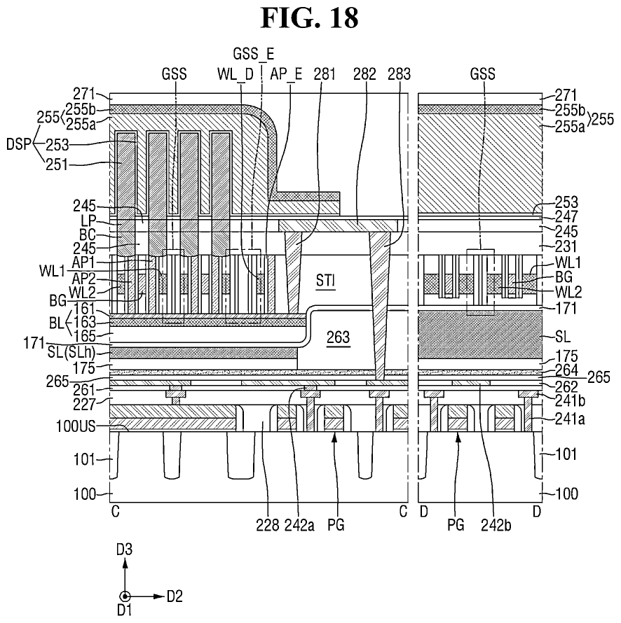

FIGS. 17 and 18 are cross-sectional views each illustrating portions of an example semiconductor memory device according to some embodiments. For simplicity of description, the following description will focus on differences from the description with reference to FIGS. 1 to 6.

Referring to FIGS. 17 and 18, the semiconductor memory device according to some embodiments may further include a bonding insulating layer 264 between the first upper insulating layer 263 and the peri-connection structures 242a and 242b.

For example, the bonding insulating layer 264 may be disposed between the first upper insulating layer 263 and the third peri-upper insulating layer 265, and between the shielding insulating capping layer 175 and the third peri-upper insulating layer 265. The bonding insulating layer 264 may include, for example, silicon carbonitride (SiCN).

Unlike the illustrated example, the third peri-upper insulating layer 265 may not be disposed on the peri-connection line 242b.

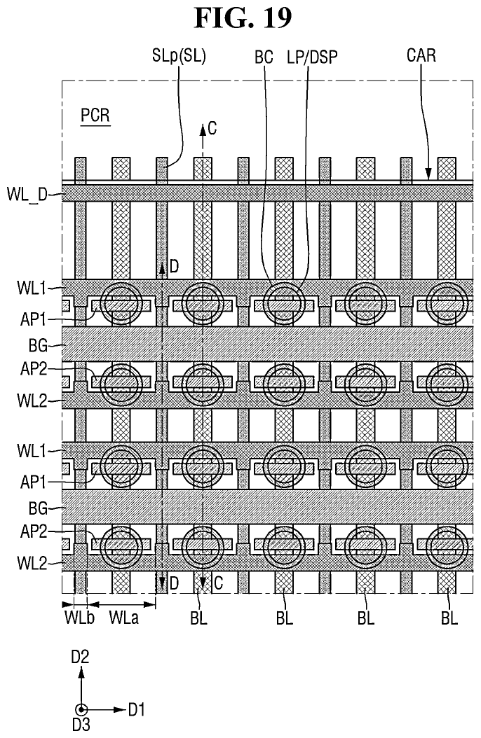

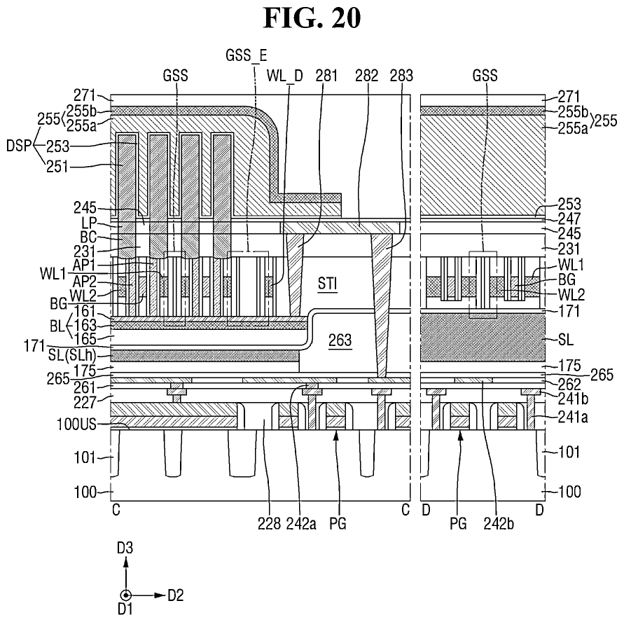

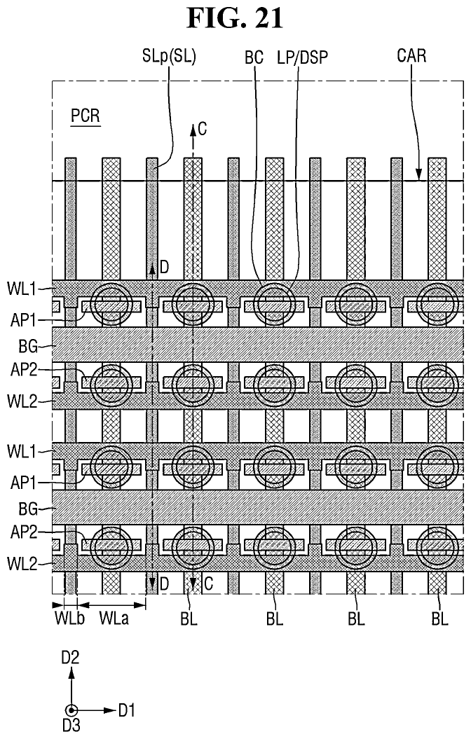

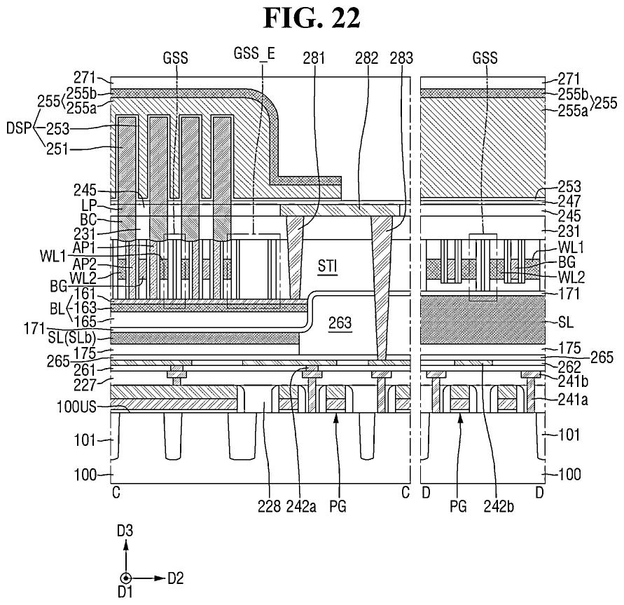

FIGS. 19 and 20 are plan and cross-sectional views, respectively, illustrating an example semiconductor memory device according to some embodiments. FIGS. 21 and 22 are plan and cross-sectional views, respectively, illustrating an example semiconductor memory device according to some embodiments. For simplicity of description, the following description will focus on differences from the description with reference to FIGS. 1 to 6.

Referring to FIGS. 19 and 20, in the semiconductor memory device according to some embodiments, the boundary dummy active patterns AP_E (see FIG. 2) are not provided along the boundary of the cell array region CAR.

The dummy word line WL_D may extend along the boundary of the cell array region CAR, i.e., along the sidewall of the cell region element isolation layer STI in the first direction D1.

Referring to FIGS. 21 and 22, the semiconductor memory device according to some embodiments may not include the boundary dummy active patterns AP_E (see FIG. 2) and the dummy word line WL_D (see FIG. 2).

The boundary dummy active patterns AP_E (see FIG. 2) and the dummy word line WL_D (see FIG. 2) are not provided along the boundary of the cell array region CAR.

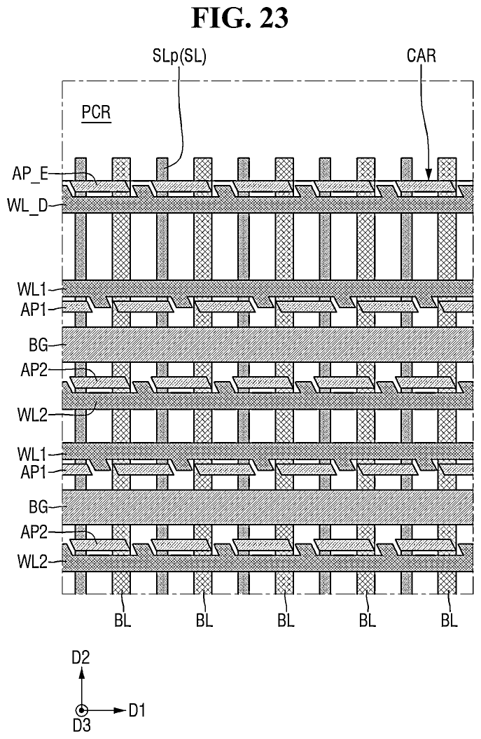

FIGS. 23 to 26 are diagrams each illustrating a semiconductor memory device according to some embodiments. For simplicity of description, the following description will focus on differences from the description with reference to FIGS. 1 to 22.

Referring to FIG. 23, in the semiconductor memory device according to some embodiments, the first and second active patterns AP1 and AP2 may be alternately arranged in an oblique direction with respect to the first and second directions D1 and D2.

In plan view, each of the first and second active patterns AP1 and AP2 may have a parallelogram shape or a rhombus shape. Since the first and second active patterns AP1 and AP2 are disposed in the oblique direction, it is possible to reduce coupling between the first and second active patterns AP1 and AP2 adjacent to and facing each other in the second direction D2.

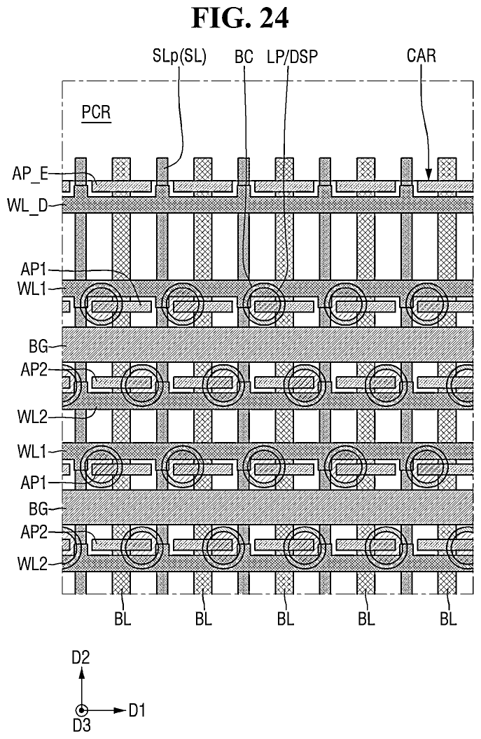

Referring to FIG. 24, in a semiconductor memory device according to some embodiments, the landing pads LP and the data storage patterns DSP may be arranged in a zigzag or honeycomb shape in plan view; that is, adjacent landing pads LP and data storage patterns DSP may be offset from one another in the second direction D2.

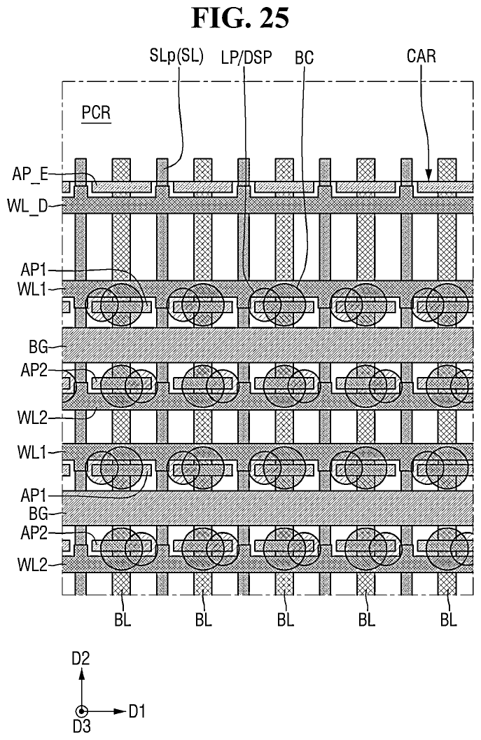

Referring to FIG. 25, in the semiconductor memory device according to some embodiments, the data storage patterns DSP may be misaligned with the landing pads LP in plan view.

Each data storage pattern DSP may be in contact with a part of the landing pad LP.

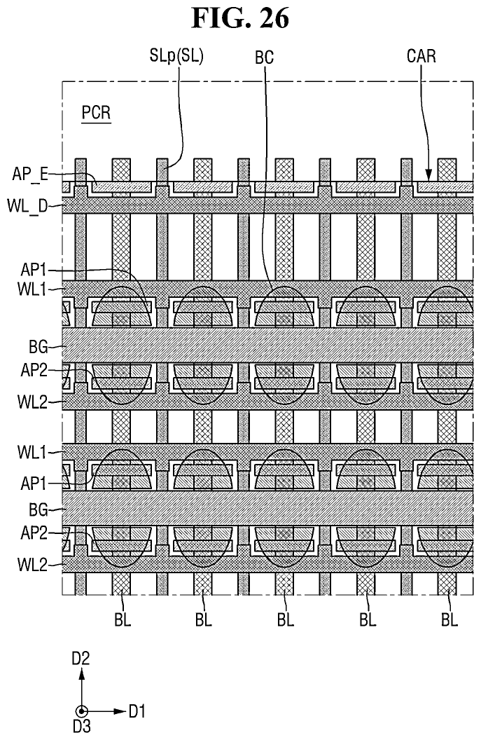

Referring to FIG. 26, in the semiconductor memory device according to some embodiments, each of the contact patterns BC disposed on the first and second active patterns AP1 and AP2 may have a semicircular shape or a semielliptical shape in plan view.

The contact patterns BC may be disposed symmetrically with each other with the back gate electrode BG interposed therebetween in plan view; that is, adjacent contact patterns BC may be spaced apart from one another in the second direction D2 by the back gate electrode BG extending in the first direction D1.

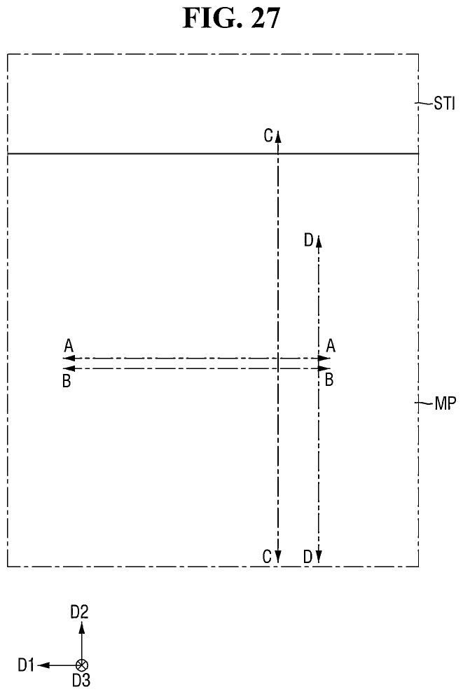

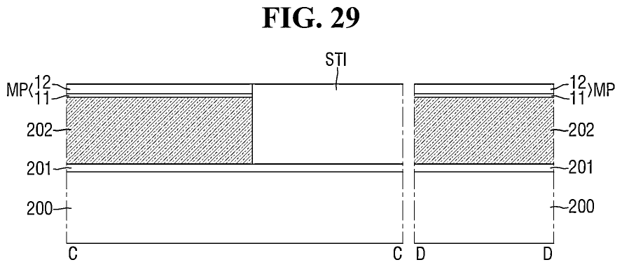

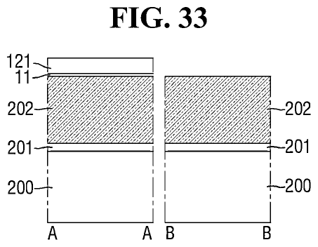

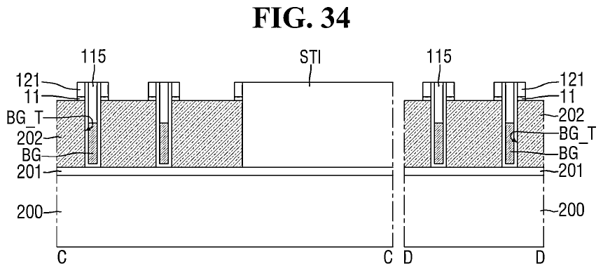

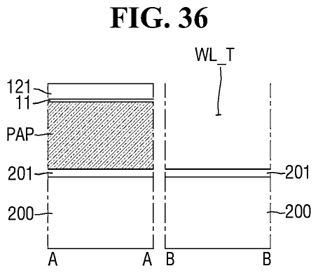

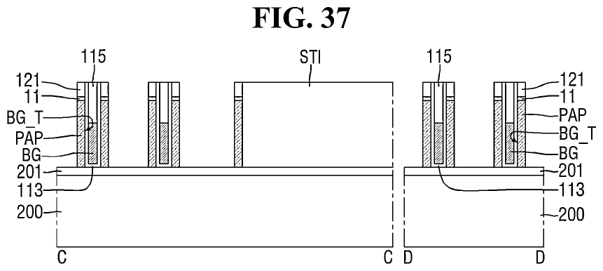

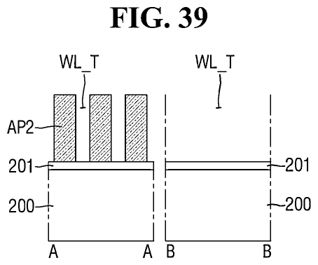

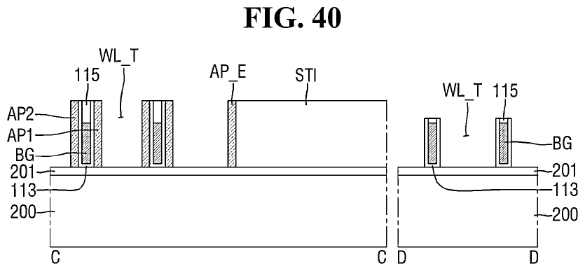

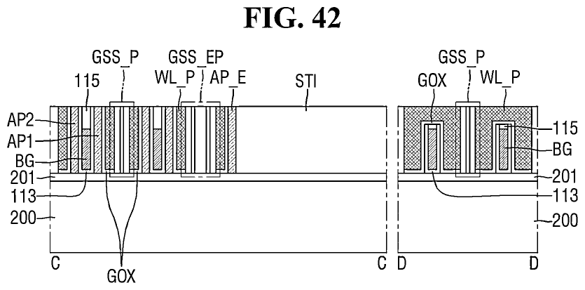

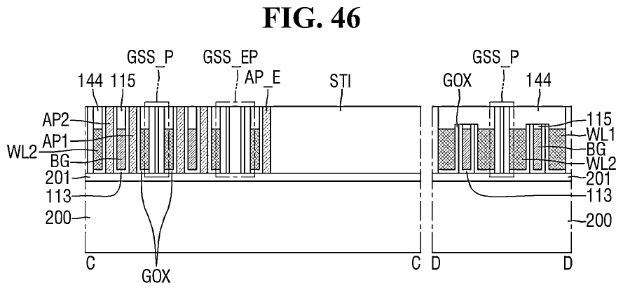

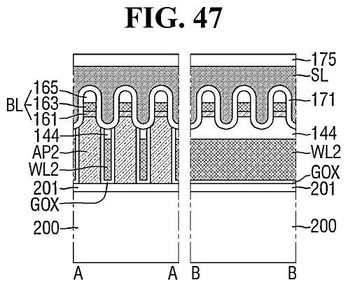

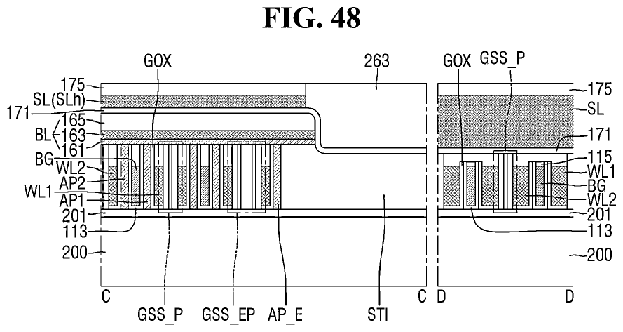

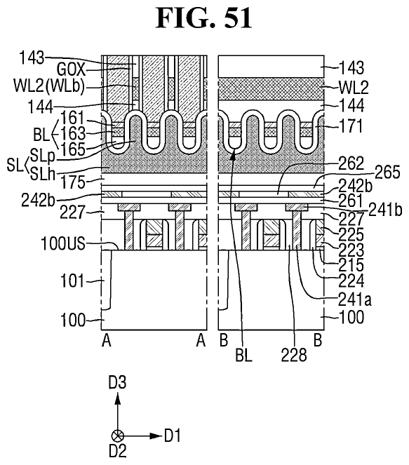

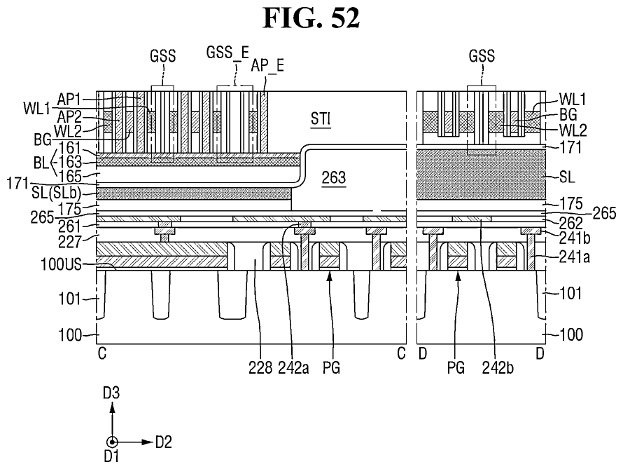

FIGS. 27 to 52 are views illustrating intermediate processes in an example method for fabricating a semiconductor memory device according to some embodiments. Through this method, the semiconductor memory device described with reference to FIGS. 1 to 6 may be fabricated.

Referring to FIGS. 27 to 29, a sub-substrate structure including a sub-substrate 200, a buried insulating layer 201, and an active layer 202 may be provided.

The buried insulating layer 201 and the active layer 202 may be provided on the sub-substrate 200. The sub-substrate 200, the buried insulating layer 201, and the active layer 202 may be a silicon-on-insulator substrate (i.e., SOI substrate).

The sub-substrate 200 may include the cell array region CAR and the peripheral circuit region PCR. The sub-substrate 200 may be, for example, a silicon substrate, a germanium substrate, and/or a silicon-germanium substrate, although embodiments are not limited thereto.

The buried insulating layer 201 may be a buried oxide (BOX) formed by a separation by implanted oxygen (SIMOX) method or a bonding and layer transfer method. Alternatively, the buried insulating layer 201 may be an insulating layer formed by a chemical vapor deposition (CVD) method. The buried insulating layer 201 may include, for example, a silicon oxide layer, a silicon nitride layer, a silicon oxynitride layer, and/or a low dielectric constant insulating layer, although embodiments are not limited thereto.

The active layer 202 may be a single crystal semiconductor layer. The active layer 202 may be, for example, a single crystal silicon substrate, a germanium substrate, and/or a silicon-germanium substrate, although embodiments are not limited thereto. The active layer 202 may have first and second surfaces that are opposite to each other in the third direction D3. The second surface of the active layer 202 may be in contact with the buried insulating layer 201.

Subsequently, a mask pattern MP may be formed on the active layer 202. The mask pattern MP may include a lower mask layer 11 and an upper mask layer 12 that are sequentially stacked in the third direction D3. The upper mask layer 12 may be formed of a material having etch selectivity with respect to the lower mask layer 11. For example, the lower mask layer 11 may include silicon oxide, and the upper mask layer 12 may include silicon nitride, but the present disclosure is not limited thereto.

Next, the cell region element isolation layer STI may be formed in the active layer 202 of the peripheral circuit region PCR. The cell region element isolation layer STI may be formed by patterning the active layer 202 of the peripheral circuit region PCR (e.g., using a standard photolithographic process) to form an element isolation trench that exposes the buried insulating layer 201, and then burying an insulating material in the element isolation trench, such as by filling the element isolation trench with an insulating material. The term “exposes” (or “expose,” or like terms) may be used herein to describe relationships between elements and/or with reference to intermediate processes in fabricating a semiconductor device, but may not require exposure of a particular element in the completed device. Likewise, the term “not exposed” may be used to described relationships between elements and/or with reference to intermediate processes in fabricating a semiconductor device, but may not require a particular element to be unexposed in the completed device. The term “filling” (or “fills,” or like terms), as may be used herein, is intended to refer broadly to either completely filling a defined space (e.g., the element isolation trench) or partially filling the defined space; that is, the defined space need not be entirely filled but may, for example, be partially filled or have voids or other spaces throughout. The cell region element isolation layer STI may be formed to define the cell array region CAR. The top surface of the cell region element isolation layer STI may be substantially coplanar with the top surface of the mask pattern MP.

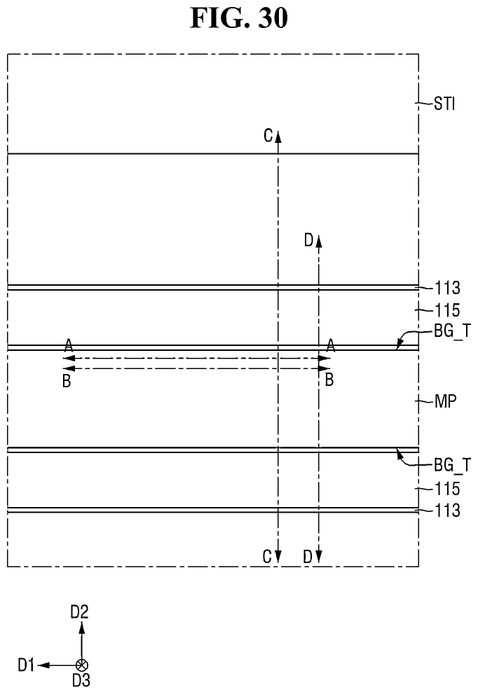

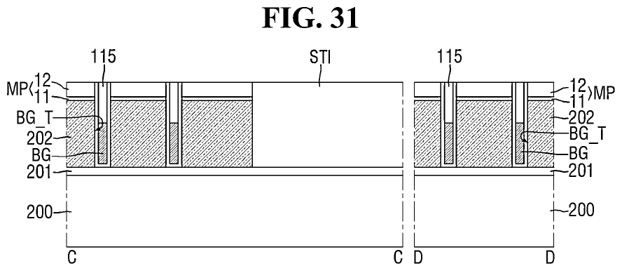

Referring to FIGS. 30 and 31, the active layer 202 of the cell array region CAR may be anisotropically etched.

Accordingly, back gate trenches BG_T extending in the first direction D1 may be formed in the active layer 202 of the cell array region CAR. The back gate trenches BG_T may expose the buried insulating layer 201 and may be spaced apart from each other by a predetermined interval in the second direction D2.

Unlike the illustrated example, at least a part of the buried insulating layer 201 may be removed while the back gate trenches BG_T are formed.

Subsequently, the back gate insulating pattern 113 and the back gate electrodes BG may be formed in the back gate trench BG_T.

More specifically, the back gate insulating pattern 113 may be formed along the sidewall and the bottom surface of the back gate trench BG_T and the top surface of the mask pattern MP. A back gate conductive layer may be formed on the back gate insulating pattern 113. The back gate conductive layer may fill the back gate trench BG_T. Next, the back gate electrodes BG may be formed to extend in the first direction D1 by etching the back gate conductive layer. The back gate electrodes BG may fill a part of the back gate trench BG_T.

Meanwhile, according to some embodiments, a gas phase doping (GPD) process or a plasma doping (PLAD) process may be performed before forming the back gate insulating pattern 113. Through the above process, the active layer 302 exposed by the back gate trench BG_T may be doped with impurities.

Subsequently, the back gate capping pattern 115 may be formed on the back gate electrode BG.

The back gate capping pattern 115 may fill the remaining part of the back gate trench BG_T. When the back gate capping pattern 115 and the back gate insulating pattern 113 are made of the same material (e.g., silicon oxide), the back gate insulating pattern 113 on the top surface of the mask pattern MP may be removed while the back gate capping pattern 115 is formed.

Meanwhile, before forming the back gate capping pattern 115, a gas phase doping (GPD) process or a plasma doping (PLAD) process may be performed. Through this process, impurities may be doped into the active layer 302 through the back gate trench BG_T in which the back gate electrode BG has been formed.

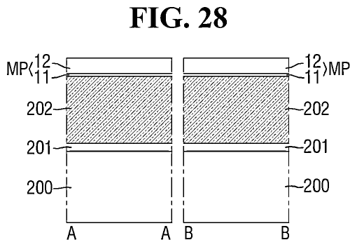

A cross-sectional view taken along lines A-A and B-B of FIG. 30 may be the same as that of FIG. 28.

Referring to FIGS. 30 to 34, after forming the back gate capping pattern 115, the upper mask layer 12 may be removed.

The back gate capping pattern 115 may have a shape that protrudes upward beyond the top surface of the lower mask layer 11.

Subsequently, a pair of spacer patterns 121 may be formed on the sidewalls of the back gate insulating pattern 113.

More specifically, a spacer layer may be formed along the top surface of the first lower mask layer 11, the sidewalls of the back gate insulating pattern 113, and the top surfaces of the back gate capping pattern 115. The spacer layer may be formed to have a uniform thickness. The spacer pattern 121 may be formed by performing an anisotropic etching process on the spacer layer. While the spacer pattern 121 is formed, the active layer 202 may be exposed.

Widths of active patterns of vertical channel transistors may be determined according to the deposition thickness of the spacer layer. The spacer layer may be made of an insulating material. The spacer layer may include, for example, silicon oxide, silicon oxynitride, silicon nitride, silicon carbide (SiC), silicon carbon nitride (SiCN), and a combination thereof.

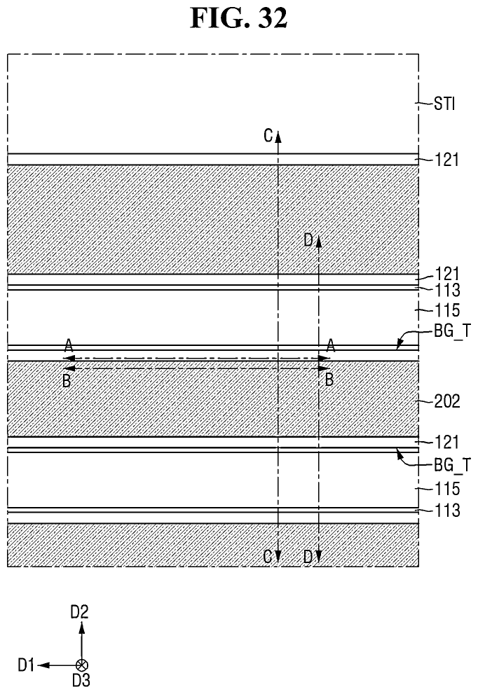

Referring to FIGS. 32 to 37, an anisotropic etching process may be performed on the active layer 202 by using the spacer pattern 121 as an etching mask.

Through this process, pre-active patterns PAP extending along the back gate electrode BG may be formed. As the pre-active patterns PAP are formed, the buried insulating layer 201 may be exposed. The pre-active patterns PAP may be formed along the sidewall of the cell region element isolation layer STI.

A word line trench WL_T may be formed between the pre-active patterns PAP adjacent to each other.

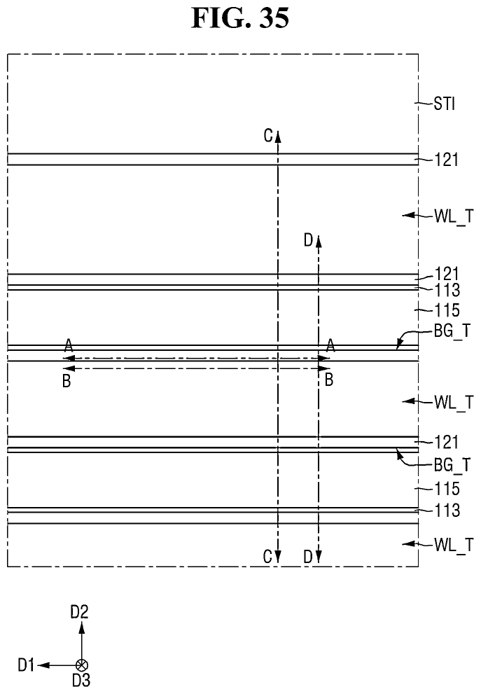

Referring to FIGS. 35 to 40, a sacrificial layer may be formed to fill the word line trench WL_T.

An active mask pattern may be formed on the sacrificial layer. The active mask pattern may have a line shape extending in the second direction D2. As another example, the active mask pattern may have a line shape extending in an oblique direction with respect to the first and second directions D1 and D2. Sacrificial openings may be formed in the sacrificial layer by etching the sacrificial layer using the active mask pattern as an etch mask.

The first active pattern AP1 and the second active pattern AP2 may be formed on both (laterally opposing) sides of the back gate electrode BG by etching the pre-active patterns PAP exposed through the sacrificial openings. The first active pattern AP1 may be formed on a first sidewall of the back gate electrode BG to be spaced apart from each other in the first direction D1. The second active pattern AP2 may be formed on a second sidewall of the back gate electrode BG to be spaced apart from each other in the first direction D1. As the first active pattern AP1 and the second active pattern AP2 are formed, the sacrificial openings may expose a part of the back gate insulating pattern 113. While the first active pattern AP1 and the second active pattern AP2 are formed, a part of the back gate capping pattern 115 exposed to the sacrificial openings may be etched.

Subsequently, the sacrificial layer, the active mask pattern, the spacer pattern 121 and the lower mask layer 11 may be removed. Through this process, the first active pattern AP1 and the second active pattern AP2 may be exposed. In addition, the buried insulating layer 201 may be exposed.

While the first active pattern AP1 and the second active pattern AP2 are formed, the boundary dummy active pattern AP_E may be formed on the sidewall of the cell region element isolation layer STI. Unlike the illustrated example, for example, the boundary dummy active pattern AP_E may not be formed on the sidewall of the cell region element isolation layer STI.

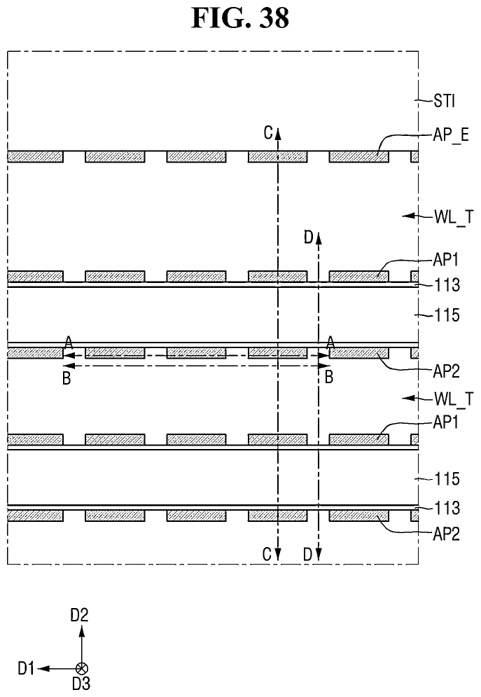

Referring to FIGS. 38 to 44, the gate insulating pattern GOX may be formed along the sidewall of the first active pattern AP1, the sidewall of the second active pattern AP2, the top surface of the back gate capping pattern 115, and the top surface of the buried insulating layer 201.

The gate insulating pattern GOX may be formed using at least one of a physical vapor deposition (PVD) method, a thermal chemical vapor deposition (thermal CVD) method, a low pressure chemical vapor deposition (LPCVD) method, a plasma enhanced chemical vapor deposition (PECVD) method, or an atomic layer deposition (ALD) method. However, the present disclosure is not limited thereto.

Subsequently, a pre-word line WL_P may be formed on the gate insulating pattern GOX. The pre-word line WL_P may be formed on the sidewalls of the first and second active patterns AP1 and AP2. The pre-word line WL_P may be formed on the sidewall of the boundary dummy active pattern AP_E. In a portion where the first active pattern AP1 and the second active pattern AP2 are not disposed, the pre-word line WL_P may be formed on the top surface of the back gate capping pattern 115.

Forming the pre-word line WL_P may include depositing a gate conductive layer on the gate insulating pattern GOX and then performing an anisotropic etching process on the gate conductive layer. Here, the deposition thickness of the gate conductive layer may be smaller than half of the width of the word line trench WL_T.

During the anisotropic etching process on the gate conductive layer, the gate insulating pattern GOX may be used as an etch stop layer. While the anisotropic etching process on the gate conductive layer is in progress, the gate insulating pattern GOX may be separated, exposing the buried insulating layer 201.

Two pre-word lines WL_P may be formed between the back gate electrodes BG adjacent in the second direction D2. The pre-word lines WL_P disposed between the adjacent back gate electrodes BG are separated from each other.

Next, a pre-gate isolation pattern GSS_P and a pre-outermost gate isolation pattern GSS_EP may be formed on the sub-substrate 200. The pre-gate isolation pattern GSS_P may be formed between the back gate electrodes BG adjacent in the second direction D2. The pre-gate isolation pattern GSS_P may be formed between the pre-word lines WL_P spaced apart in the second direction D2. The pre-outermost gate isolation pattern GSS_EP may be formed between the outermost back gate electrode BG and the cell region element isolation layer STI. For example, the top surface of the cell region element isolation layer STI may be coplanar with the top surface of the pre-gate isolation pattern GSS_P and the top surface of the pre-outermost gate isolation pattern GSS_EP.

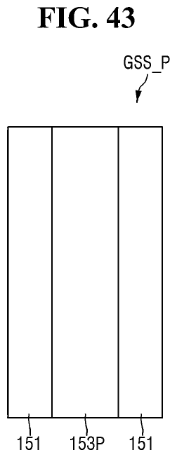

In FIG. 43, the pre-gate isolation pattern GSS_P may include the gate isolation spacers 151 and a sacrificial isolation pattern 153P. The sacrificial isolation pattern 153P may be formed between the gate isolation spacers 151 adjacent in the second direction D2.

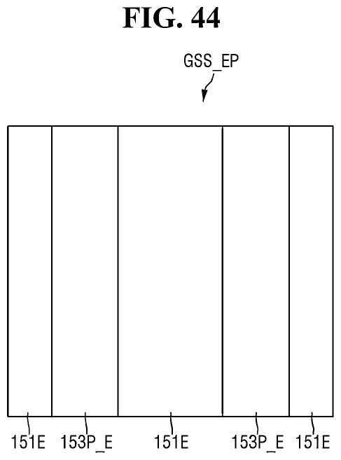

In FIG. 44, the pre-outermost gate isolation pattern GSS_EP may include a plurality of outermost sacrificial isolation patterns 153P_E. The pre-outermost gate isolation pattern GSS_EP may include the outermost gate isolation spacers 151E. Each of the outermost sacrificial isolation patterns 153P_E may be formed between the outermost gate isolation spacers 151E adjacent in the second direction D2.

The sacrificial isolation pattern 153P and the outermost sacrificial isolation pattern 153P_E may include a material having an etch selectivity with respect to the gate isolation spacer 151 and the outermost gate isolation spacer 151E.

Unlike the illustrated example, when the sacrificial isolation pattern 153P is the gate isolation low-k material 153LK (see FIG. 8), the pre-gate isolation pattern GSS_P may be the gate isolation pattern GSS (see FIG. 8). Since the outermost sacrificial isolation pattern 153P_E may be the outermost gate isolation low-k material 153LK_E, the pre-outermost gate isolation pattern GSS_EP may be the outermost gate isolation pattern GSS_E (scc FIG. 8).

Thereafter, a part of the sacrificial isolation pattern 153P may be removed to form an isolation recess between the gate isolation spacers 151. The low-k capping pattern 155 (see FIG. 5) may be formed in the isolation recess. By removing a part of the outermost sacrificial isolation pattern 153P_E, an outermost isolation recess may be formed between the outermost gate isolation spacers 151E. The outermost low-k capping pattern 155E (see FIG. 5) may be formed in the outermost isolation recess.

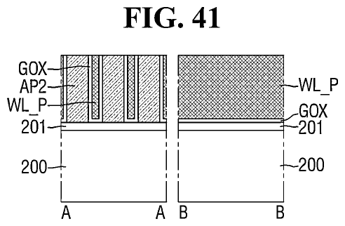

Referring to FIGS. 41, 42, 45, and 46, a part of the pre-word line WL_P may be removed to form the first word line WL1 and the second word line WL2.

The top surfaces of the first and second word lines WL1 and WL2 may be positioned at a lower level than the top surfaces of the first and second active patterns AP1 and AP2 relative to a top surface of the sub-substrate 200.

For example, after forming the first and second word lines WL1 and WL2, a gas phase doping (GPD) process or a plasma doping (PLAD) process may be performed. Through this process, impurities may be doped into the first and second active patterns AP1 and AP2 through the gate insulating pattern GOX exposed by the first and second word lines WL1 and WL2.

Subsequently, the gate shielding pattern 144 may be formed on the first word line WL1 and the second word line WL2. In a portion where the first active pattern AP1 and the second active pattern AP2 are not disposed, the gate shielding pattern 144 may be formed on the top surface of the back gate capping pattern 115.

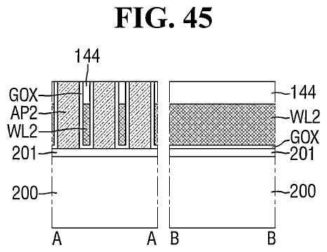

Referring to FIGS. 45 to 48, the bit line BL may be formed on the first active pattern AP1 and the second active pattern AP2.

The bit line BL may be electrically connected to the first active pattern AP1 and the second active pattern AP2.

Subsequently, the shielding insulating liner 171 may be formed along the profile of the bit line BL. The shielding conductive pattern SL and the shielding insulating capping layer 175 may be formed on the shielding insulating liner 171. For example, the shielding conductive pattern SL and the shielding insulating capping layer 175 may be sequentially stacked in the third direction D3 on the shielding insulating liner 171.

Next, the first upper insulating layer 263 may be formed on the shielding insulating liner 171. The first upper insulating layer 263 may cover the sidewall of the shielding conductive pattern SL and the sidewall of the shielding insulating capping layer 175. The top surface of the first upper insulating layer 263 may lie on the same plane as the top surface of the shielding insulating capping layer 175 relative to the top surface of the sub-substrate 200; that is, the top surface of the first upper insulating layer 263 and the top surface of the shielding insulating capping layer 175 may be coplanar.

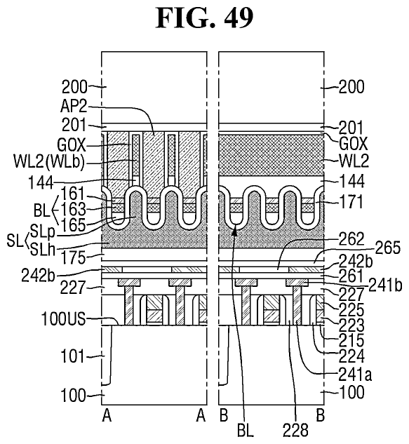

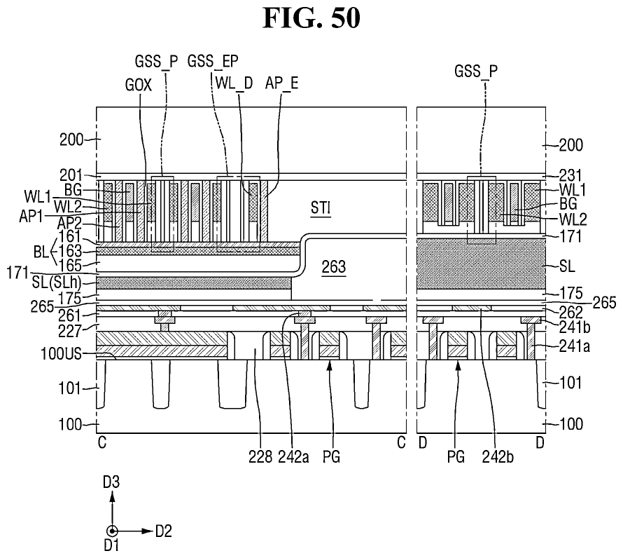

Referring to FIGS. 49 and 50, the sub-substrate 200 on which the back gate electrodes BG, the word lines WL1 and WL2, the active patterns AP1 and AP2, the bit lines BL, the pre-gate isolation patterns GSS_P, the pre-outermost gate isolation pattern GSS_EP, and the shielding conductive pattern SL are formed may be bonded (or otherwise attached) to the substrate 100.

In other words, the substrate 100 on which the peri-gate structure PG and the peri-connection structures 242a and 242b are formed may be bonded to the sub-substrate 200.

Referring to FIGS. 49 to 52, after bonding the sub-substrate 200 to the substrate 100, a rear lapping process (e.g., chemical-mechanical polishing (CMP), etc.) may be performed to remove the sub-substrate 200.

Removing the sub-substrate 200 may include exposing the buried insulating layer 201 by sequentially performing a grinding process and a wet etching process, although embodiments are not limited thereto.

Subsequently, the first active pattern AP1 and the second active pattern AP2 may be exposed by removing the buried insulating layer 201.

As the buried insulating layer 201 is removed, a part of the gate insulating pattern GOX and a part of the back gate insulating pattern 113 may be exposed.

Thereafter, the exposed gate insulating pattern GOX and the exposed back gate insulating pattern 113 may be removed. Through this process, the back gate electrode BG, the first word line WL1 and the second word line WL2 may be exposed.

Subsequently, a part of the first word line WL1 and a part of the second word line WL2 may be removed by performing an etch-back process, whereby the top surfaces of the first word line WL1 and the second word line WL2 are recessed in the third direction D3 (e.g., below the top surfaces of the first and second active patterns AP1 and AP2). The gate capping pattern 143 may be formed on the recessed first and second word lines WL1 and WL2.

A part of the back gate electrode BG may be removed by performing an etch-back process. The back gate isolation pattern 111 may be formed on the recessed back gate electrode BG.

The buried insulating layer 201 may be removed to expose the pre-gate isolation pattern GSS_P and the pre-outermost gate isolation pattern GSS_EP. For example, the sacrificial isolation pattern 153P and the outermost sacrificial isolation pattern 153P_E may be exposed.

By removing the sacrificial isolation pattern 153P, an isolation space may be formed between the gate isolation spacers 151 (see FIG. 5). The low-k capping pattern 155 (see FIG. 5) may fill a part of the isolation space. Through this process, the gate isolation air gap 153AG (see FIG. 5) may be formed between the gate isolation spacers 151 adjacent in the second direction D2. By removing the outermost sacrificial isolation pattern 153P_E, an outermost isolation space may be formed between the outermost gate isolation spacers 151E (see FIG. 5). The outermost low-k capping pattern 155E (see FIG. 5) may fill a part of the outermost isolation space. Through this process, the outermost gate isolation air gap 153AG_E (see FIG. 5) may be formed between the outermost gate isolation spacers 151E.

Referring to FIGS. 3 and 4, contact holes exposing the first and second active patterns AP1 and AP2 may be formed in the contact interlayer insulating layer 231. The contact pattern BC may be formed in the contact hole. The contact pattern BC may be formed on the first active pattern AP1 and the second active pattern AP2. The contact pattern BC may be connected to the first active pattern AP1 and the second active pattern AP2.

The bit line contact plug 281 connected to the bit line BL may be formed. The upper peripheral contact plug 283 may be formed. The upper peripheral contact plug 283 connected to the peri-connection line 242b may be formed.

Subsequently, the landing pad LP may be formed on the contact pattern BC. The landing pad LP may be formed in the pad isolation insulating layer 245. The upper connection line 282 may be formed in the pad isolation insulating layer 245. The upper connection line 282 may connect the bit line contact plug 281 to the upper peripheral contact plug 283.

Subsequently, the data storage patterns DSP may be formed on the landing pads LP.

Although the embodiments of the present disclosure have been described with reference to the accompanying drawings, the present disclosure is not limited to the above embodiments and may be implemented in various different forms. Those of ordinary skill in the technical field to which the present disclosure belongs will be able to understand that the present disclosure may be implemented in other specific forms without changing the technical idea or essential characteristics of the present disclosure. Therefore, it should be understood that the embodiments as described above are not restrictive but illustrative in all respects.

What is claimed is:

1. A semiconductor memory device, comprising:
a bit line extending in a first direction on a substrate, the first direction parallel to a top surface of the substrate;
an active pattern on the bit line, and comprising a first sidewall and a second sidewall opposite to each other in the first direction, and a first surface and a second surface opposite to each other in a vertical direction perpendicular to the top surface of the substrate, the first surface of the active pattern being electrically connected to an active pattern connected to the bit line;
a word line on a first sidewall of the active pattern and extending in a second direction, the second direction parallel to the top surface of the substrate and intersecting the first direction;
a back gate electrode on a second sidewall of the active pattern and extending in the second direction;
a gate isolation pattern on a first sidewall of the active pattern, and comprising a low-dielectric constant (low-k) pattern extending in the second direction; and
a data storage pattern electrically connected to the second surface of the active pattern,
wherein the word line is between the active pattern and the gate isolation pattern, and
a distance between the bit line and the word line in the vertical direction is greater than a distance between the bit line and the low-k pattern in the vertical direction.

2. The semiconductor memory device of claim 1, wherein a height of the low-k pattern in the vertical direction is greater than a height of the word line in the vertical direction relative to the top surface of the substrate as a reference base layer.

3. The semiconductor memory device of claim 1, wherein the low-k pattern comprises an air gap.

4. The semiconductor memory device of claim 3, wherein the air gap is not in contact with the bit line.

5. The semiconductor memory device of claim 1, wherein the low-k pattern comprises a low-k material, and
a dielectric constant of the low-k material is less than a dielectric constant of silicon oxide.

6. The semiconductor memory device of claim 1, wherein the low-k pattern comprises an upper low-k pattern and a lower low-k pattern,
the low-k pattern is between the bit line and the upper low-k pattern in the vertical direction,
the upper low-k pattern is an air gap, and
the low-k pattern is formed of a low-k material having a dielectric constant less than a dielectric constant of silicon oxide.

7. The semiconductor memory device of claim 1, wherein the word line comprises a first surface and a second surface opposite to each other in the vertical direction, and
the first surface of the word line and the second surface of the word line are concave curved surfaces.

8. The semiconductor memory device of claim 1, wherein the gate isolation pattern comprises a plurality of low-k patterns.

9. The semiconductor memory device of claim 1, further comprising a shielding conductive pattern on the substrate,
wherein the shielding conductive pattern comprises a shielding conductive plate and a plurality of shielding conductive protrusion patterns extending in the vertical direction from the shielding conductive plate, and
each of the plurality of shielding conductive protrusion patterns extends in the first direction.

10. The semiconductor memory device of claim 9, wherein the bit line is between shielding conductive protrusion patterns of the plurality of shielding conductive protrusion patterns adjacent in the second direction.

11. The semiconductor memory device of claim 1, wherein the word line comprises a first portion and a second portion alternately disposed in the second direction, and
a width of the first portion of the word line in the first direction is less than a width of the second portion of the word line in the first direction.

12. A semiconductor memory device, comprising:
a bit line extending in a first direction on a substrate, the first direction parallel to a top surface of the substrate;
a first active pattern on the bit line;
a second active pattern on the bit line and spaced apart from the first active pattern in the first direction;
a first word line between the first active pattern and the second active pattern and extending in a second direction, the second direction parallel to the top surface of the substrate and intersecting the first direction;
a second word line between the first active pattern and the second active pattern, extending in the second direction, and spaced apart from the first word line in the first direction;
a gate isolation pattern between the first word line and the second word line on the bit line, and comprising a low-k pattern extending in the second direction;
a back gate electrode on the bit line, spaced apart from the first word line and the second word line in the first direction, and extending in the second direction; and
data storage patterns electrically connected to the first active pattern and the second active pattern,
wherein a height of the low-k pattern in a vertical direction is greater than a height of the first word line in the vertical direction, relative to the top surface of the substrate as a base reference layer, the vertical direction perpendicular to the top surface of the substrate.

13. The semiconductor memory device of claim 12, wherein a distance between the bit line and the first word line in the vertical direction is greater than a distance between the bit line and the low-k pattern in the vertical direction.

14. The semiconductor memory device of claim 12, wherein the low-k pattern is an air gap, and
the air gap is not in contact with the bit line.

15. The semiconductor memory device of claim 12, wherein the low-k pattern is formed of a low-k material, and
a dielectric constant of the low-k material is less than a dielectric constant of silicon oxide.

16. The semiconductor memory device of claim 12, wherein the low-k pattern comprises an upper low-k pattern and a lower low-k pattern,
the low-k pattern is between the bit line and the upper low-k pattern in the vertical direction,
the upper low-k pattern is an air gap, and
the low-k pattern is formed of a low-k material having a dielectric constant less than a dielectric constant of silicon oxide.

17. The semiconductor memory device of claim 12, wherein each of the first word line and the second word line comprises a first surface and a second surface opposite to each other in the vertical direction, and
the first surface of each of the first and second word lines and the second surface of each of the first and second word lines are concave curved surfaces.

18. A semiconductor memory device, comprising:
a peri-gate structure on a substrate;
a shielding conductive pattern on the peri-gate structure, and comprising a shielding conductive plate and a plurality of shielding conductive protrusion patterns extending from the shielding conductive plate in a vertical direction perpendicular to a top surface of the substrate, each of the shielding conductive protrusion patterns extending in a first direction;
bit lines between the shielding conductive protrusion patterns adjacent to each other in a second direction, on the shielding conductive plate, the second direction parallel to the top surface of the substrate and intersecting the first direction;
back gate electrodes on the bit lines and extending in the second direction;
a first word line and a second word line between the back gate electrodes adjacent in the first direction on the bit line and extending in the second direction;
first active patterns between the back gate electrodes and the first word line, the first active patterns electrically connected to the respective bit lines and arranged in the second direction;
second active patterns between the back gate electrodes and the second word line, the second active patterns electrically connected to the respective bit lines and arranged in the second direction;
a gate isolation pattern between the first word line and the second word line on the bit line, the gate isolation pattern comprising one or more low-dielectric constant (low-k) patterns extending in the second direction; and
data storage patterns connected to the respective first active patterns and the respective second active patterns,
wherein a height of the one or more low-k patterns in the vertical direction is greater than a height of the first word line in the vertical direction relative to the top surface of the substrate as a reference base layer,
each of the one or more low-k patterns comprises one of an air gap and a low-k material, and
a dielectric constant of the low-k material is less than a dielectric constant of silicon oxide.

19. The semiconductor memory device of claim 18, further comprising an outermost gate isolation pattern on the bit lines and extending in the second direction,
wherein the outermost gate isolation pattern comprises one or more outermost low-k patterns, and
a first number of the outermost low-k patterns comprised in the outermost gate isolation pattern is greater than a second number of the low-k patterns comprised in the gate isolation pattern.

20. The semiconductor memory device of claim 18, wherein a distance between a given one of the bit lines and the first word line in the vertical direction is greater than a distance between the given one of the bit lines and a given one of the one or more low-k patterns in the vertical direction.
